(19) United States
(12) Patent Application Publication
(10) Pub. No.: US 2015/0377935 A1
(43) Pub. Date: Dec. 31, 2015

(54) SIGNAL IDENTIFICATION METHODS AND SYSTEMS

(71) Applicant: BOARD OF REGENTS OF THE NEVADA SYSTEM OF HIGHER EDUCATION, ON BEHALF OF THE DESERT RESEARCH INSTIT, Reno, NV (US)

(72) Inventors: Hampden Kuhns, Reno, NV (US); Morien Roberts, Reno, NV (US)

(73) Assignee: BOARD OF REGENTS OF THE NEVADA SYSTEM OF HIGHER EDUCATION, ON BEHALF OF THE DESERT RESEARCH INSTIT, Reno, NV (US)

(21) Appl. No.: 14/812,992

(22) Filed: Jul. 29, 2015

Related U.S. Application Data
(62) Division of application No. 13/360,474, filed on Jan. 27, 2012, now abandoned.
(60) Provisional application No. 61/437,454, filed on Jan. 28, 2011.

(51) Int. Cl. G01R 19/25; G01R 22/10

(52) U.S. Cl. CPC G01R 19/2513; G01R 22/10

(57) ABSTRACT

Disclosed herein are signal identification methods and systems. In some examples, the method and/or system allows appliances to be associated with their electrical usage. In one example, a method for determining whether a load is in a steady state or in transition includes analyzing a time series of electric power or current measurements on at least one circuit, at least one load coupled to the at least one circuit; and determining whether the load is in a steady state or a transition. Also disclosed is an appliance identification method. Further disclosed is a method of mapping unlabeled appliances which utilizes a STEC Table which summarizes linkages between transitions and steady state clusters.

### CROSS REFERENCE TO RELATED APPLICATION

This application claims priority to U.S. Provisional Application No. 61/437,454 filed Jan. 28, 2011, herein incorporated by reference in its entirety.

### ACKNOWLEDGEMENT OF GOVERNMENT SUPPORT

This invention was made with government support under Grant No. 0912914 awarded by the National Science Foundation, Grant Nos. DE-FG36-08G088161 and DE-FG30-08CC00057 awarded by the United States Department of Energy. The government has certain rights in the invention.

### FIELD

The present disclosure relates generally to methods and systems of signal identification. In some examples, the method and/or system allows appliances to be associated with their electrical usage.

### SUMMARY

Disclosed herein are signal identification methods and systems. In one embodiment, a method for determining whether a load is in a steady state or in transition is disclosed. In some embodiments, the method includes analyzing a time series of electric power or current measurements on at least one circuit, at least one load coupled to the at least one circuit; and determining whether the load is in a steady state or a transition.

In some embodiments, the method further comprises comparing the average and variance of the time series.

In some embodiments, the method further comprises comparing the absolute value of a value obtained by comparing the average and variance of a time series to a threshold.

In some embodiments, the method further comprises determining that the load is in transition when the absolute value if greater than the threshold.

Also disclosed are methods for tracking the state of an appliance. In some embodiments, a method for tracking the state of an appliance comprises determining a power sequence for a steady state electrical signal; calculating steady state and transition waveforms for the power sequence; clustering steady state waveforms, with each cluster representing the same set of appliances being either on and or off; clustering transition waveforms with each cluster representing the same transition, on or off or a change in power usage (such as change to a higher or lower power usage state) for an appliance; determining a sequence of clustered transition waveforms that represent a complete on-off cycling of all appliances that changed state during the time period of the steady state waveforms.

In some embodiments, the method further comprises determining a closure rule, the closure rule comprising, for a particular steady state, determining the transition sequence to the next steady state in the same steady state cluster. The length of a closure rule is the number of transitions in the sequence.

In some embodiments, the method further comprises eliminating closure rules that are not related to real appliances.

Also disclosed are methods for resolving the operational state of an appliance by matching one or more appliances to a single event, the method comprising obtaining power transition data from a monitored circuit, the power transition data associated with one or more appliances turning on or off; determining at least one power signature from the power transition data; comparing the power signature to a library of power signatures; if the comparison indicates a match with a library member, associating the measured power signature with the appliance associated with the library power signature; if the measured power signature does not match a library member, adding the measured signature to the library as a new unconfirmed appliance.

In some embodiments of the method, the library contains unconfirmed appliance signatures, further comprising comparing the measured signature to combinations of unconfirmed appliance signatures in the library.

In some embodiments, the method further comprises extracting an elemental appliance signature from a combination signature produced by combining unconfirmed appliance signatures in the library.

Also disclosed is an appliance identification method. In some embodiments, the method includes determining the set of closure rules of size two that begin at a new steady state; determining defined steady states from the set of closure rules of size two; and adding defined steady states to a set of defined steady states.

In some embodiments, the set of defined steady states initially consists of the steady state that uses the least amount of power.

In some embodiments, the set of defined steady states initially consists of the defined steady state corresponding to all loads associated with a monitored circuit consuming zero energy.

In some embodiments, the method further comprises determining closure rules of size 3 that apply to the set of defined steady states.

In some embodiments, the method further comprises determining closure rules of size 4 or greater that apply to the set of defined steady states.

In some embodiments, the method further comprises identifying appliances having multiple interrelated states of operation.

In some embodiments, the method further comprises identifying multiple appliances that produce identical transition signatures.

In some embodiments, the method further comprises identifying loads that give rise to redundant steady states.

Also disclosed is a method of mapping unlabeled appliances, such as a method of mapping transitions to unlabeled appliances. In some embodiments, the method comprises, determining one or more inconsistent steady states in a first Start Transition End Count (STEC) table; the first STEC table comprising a plurality of STEC records representing a plurality of transitions between a plurality of steady states; removing trivial STEC entries in which the start and end steady states are the same; resolving the one or more inconsistent steady states by merging STEC records in which differ only in the transition; and querying the first STEC table to map at least one of the plurality of transitions to one or more unlabeled appliances.

In some embodiments, each of the STEC records comprises a start steady state, a transition, and an end steady state, the start steady state and the end steady state belong to the plurality of steady states, the transition belonging to the plurality of transitions.

Also disclosed is a method for a labeling system to identify individual signals. In some embodiments, the method includes presenting results of a Non-Intrusive Appliance Load Monitoring (NIALM) disaggregated load isolation data; and providing an interface that allows a user to label and identify the individual signals.

In some embodiments, the individual signals are within one or more appliances.

In some embodiments, the method is used to monitor energy consumption in a residential setting.

In some embodiments, the method is used to monitor energy in a commercial setting, such as a Quick Serve industry.

In some embodiments, the method is used to compare the appliance transitions and power usage against snapshots of the appliance transitions and power usage taken periodically over time. Anomalies may indicate potential problems with the appliance. Users can be notified via an electronic alarm; maintenance service call can be automatically scheduled.

The foregoing and other features of the disclosure will become more apparent from the following detailed description of several embodiments which proceeds with reference to the accompanying figures.

### BRIEF DESCRIPTION OF THE DRAWINGS

Various embodiments are shown and described in connection with the following drawings in which:

FIG. 1 is a graph of circuit power versus time for examples of different Z parameters used to distinguish the operational state of a small appliance switched on and off over a noisy background.

FIG. 2 is a graph of circuit power versus time illustrating steady state boundaries using a threshold of Z=60, an averaging window of j=2 seconds, and a gap k=2 seconds.

FIG. 3 is a graph of circuit power versus time illustrating steady state boundaries using the same data as FIG. 2, but with an absolute Z threshold of 30.

FIG. 4 is a graph of circuit power versus time illustrating five periods, or segments, in each power sequence: Beginning Transition, Beginning Steady State, Middle Steady State, End Steady State, or End Transition.

FIG. 5 is a graph of power versus time for a power time series of total power, spa blower power, spa heater power, and spa pump.

FIG. 6 is a diagram allowing visualization of power steady state circles (SSᵢ) and transition lines (Tⱼ) for a simple case of two loads on a circuit. The white/black color of the pie pieces in the steady state circle represent the state of loads on the circuit (i.e. a black upper left quadrant indicates that Load A is on, etc.). For notational purposes negative power transitions have even indices and are represented via dashed lines.

FIG. 7 presents a State diagram of a trivial Closure Rule, CR, of length 1 (left panel) and a State diagram illustrating a closure rule of length 2 (right panel).

FIG. 8 presents a Steady State diagram of a less connected system.

FIG. 9 is a diagram illustrating additional CR size 3 scenarios.

FIG. 10 presents a State Diagram with separate/redundant transition T₈ running adjacent to T₄.

FIG. 11 presents a State diagram of a multistate appliance.

FIG. 12 presents a State diagram with STEC records matching (in grey) on one steady state and one transition.

FIG. 13 presents a State diagram with STEC records matching on two steady states.

FIG. 14 is a usage table illustrating unpopulated, no labeled appliances, usage breakdown.

FIG. 15 is a usage table illustrating populated usage breakdown.

FIG. 16 is a profile showing an Unlabeled Time Series of Energy usage over a user selectable period of time.

FIG. 17 is a profile showing a Trained Energy Time Series.

FIG. 18 is a digital image and schematic illustrating data flowing from an installed device is transmitted, such as wirelessly transmitted to a second device such as a mobile device, including, but not limited to laptop computer. The energy management application can be customized for different users i.e. Commercial, Home, and/or Industrial users.

FIG. 19 is a screen shot of an initial login screen of a disclosed energy management application in which users enter the user name and password.

FIG. 20 is a screen shot of a Multisite Franchise Energy Dashboard of a disclosed energy management application illustrating the portion various appliances contribute to the overall energy bill per month at different store locations.

FIG. 21 presents a screen shot of an exemplary home page for the disclosed energy management application which provides a user actionable information and overview of one or more facility's energy consumption.

FIG. 22 presents a screen shot of an exemplary home page in which the bottom charts show Usage Type as an example for category. The top right shows energy consumption by the hour for the last 24 hours.

FIG. 23 is a screen shot of the Energy Explorer feature which provides a list of all Equipment grouped by Category in a hierarchical view. Users can collapse or expand the view. The light bulb icon indicates which equipment is currently on. When the user clicks on an Equipment one can see the details on the right. Users are able to view the Energy consumption and cost details and also choose a custom date range.

FIG. 24 is a screen shot of the report feature of an energy management application which allows a user to create a report by Category analysis (by location, usage type etc.), Equipment or by creating a top 10 list.

FIG. 25 is a screen shot of a report illustrating the Energy Consumption and Cost comparison by Category for a chosen time range by day.

FIG. 26 is a screen shot of a report presenting the top 10 Equipments by energy consumption or cost for a chosen time range.

FIG. 27 is a screen shot of a Setup Menu illustrating various functions which a user may select to assist in setting up the energy management application.

FIG. 28 is a screen shot of a Help Menu showing the features available to a user.

FIG. 29 is a schematic of an exemplary computing environment for performing aspects of the disclosed methods.

FIG. 30 is a schematic of an exemplary environment for performing aspects of the disclosed methods and systems.

### DETAILED DESCRIPTION OF SEVERAL EMBODIMENTS

Unless otherwise explained, all technical and scientific terms used herein have the same meaning as commonly understood by one of ordinary skill in the art to which this disclosure belongs. In case of conflict, the present specification, including explanations of terms, will control. The singular terms “a,” “an,” and “the” include plural referents unless context clearly indicates otherwise. Similarly, the word “or” is intended to include “and” unless the context clearly indicates otherwise. The term “comprising” means “including;” hence, “comprising A or B” means including A or B, as well as A and B together. Although methods and materials similar or equivalent to those described herein can be used in the practice or testing of the present disclosure, suitable methods and materials are described herein. The disclosed materials, methods, and examples are illustrative only and not intended to be limiting.

Although the below described embodiments can be implemented in a number of ways, in at least some implementations, electrical signals are sample using 12 bits at 3840 Hz. That is, 12 bits at 64 samples per 60 Hz cycle.

Additionally, the description sometimes uses terms like “produce” and “provide” to describe the disclosed methods. These terms are high-level abstractions of the actual computer operations that are performed. The actual computer operations that correspond to these terms will vary depending on the particular implementation and are readily discernible by one of ordinary skill in the art.

Introduction

Non-intrusive appliance load monitoring (NIALM) is a technique to provide disaggregated feedback by monitoring electrical current flow into the house at the circuit breaker box. A computer algorithm to separate individual loads was first developed in 1992. Over the past decade NIALM methods have improved. These approaches largely focus on using the metrics associated with the transition period when an appliance turns on or off and have accuracies of 80% to 95%.

Although NIALM methods have improved, a number of shortcomings still exist (i.e. Variable Loads, Multistate Loads, Same Load Appliances (appliances with indistinguishable loads that have identical transitions), and Always On Loads). The present disclosure provides techniques to address a number of these shortcomings including variable loads, multistate loads and same load appliances. Examination of archived NIALM datasets from residential testing, revealed that it was necessary to separate the on transition signatures from the off transition signatures of appliances. However separating these created a new problem in that an approach was needed to link those two unrelated transition signatures to a single appliance.

Disclosed herein is the use of closure rules to link the two unrelated transition signatures to a single appliance. Closure rules exploit the fact that the baseline power signature of a circuit should be the same before and after an appliance is used when no other appliance changes state. If the steady state before the “on” event is the same as the steady state after the “off” event, a closure rule can be generated to link these two transitions to the one appliance. Using this rule, transition signatures from appliances that turn on and off with different amounts of power (i.e. refrigerators, fluorescent lights, HVAC fans, and the like) can be linked. In most cases, an appliance's “on” transition will not immediately be followed by the corresponding “off” transition, but whenever a steady state is observed to repeat a closure rule is created that implies all appliances actuated in the interim have returned to their original state. As closure rules are accumulated, the more complex rules can by simplified by eliminating the shorter and simpler rules within them. For example, a light may be on for two hours and the oven may run while the light is on. The power cycles of the oven may be removed from the light's closure rule leaving the matching on and off transitions of the light.

Based on these principals, the disclosed methods and systems can efficiently process at least a week's duration of data and extract closure rules that range in length from the trivial (rule of length one), to simple switching of a two state load (rule of length two), to matching combined transitions of two loads that turn on at the same time (rule of length three), and interleaved two appliance actuation (rule of length four). More complex rules involving interleaved switching of three or more appliances can also be detected and solved using transition linkages extracted from shorter rules. The disclosed methods and systems therefore address the short coming of Variable Loads that have on and off transitions that are not simply the inverse of one another.

The disclosed methods and systems also address the Multistate Loads (i.e. load such as front loading washer, plasma TV, or Variable Speed Drive (VSD)) issue by identifying matched loads that only occur when a baseline load is present. The methods disclosed herein utilize closure rules that reduce these complex loads to a finite set that only occur when the baseline load is present. This feature enables the algorithm to automatically find Multistate Loads without user intervention.

Prior to the methods and systems disclosed herein which utilize closure rules, NIALM techniques could not distinguish if two identical sequential transitions represented two identical appliances changing state or that the algorithm had not detected one of the inverse transitions. Application of closure rules enable multiple instances of indistinguishable loads to exist concurrently. Although the multiple appliances are indistinguishable, this information can be used to detect if one of the group begins to malfunction and cease to consume power in the same way as the other members of the group.

A desired result of the disclosed NIALM system is to display to a user the disaggregated energy consumption and cost of the major energy consuming appliances in a building. The disaggregated consumption is derived from measurements of the total energy consumption of the building. The disclosed NIALM system allows for at least the following: monitoring the current and voltage flowing into a building; determining when a significant change in power, i.e. an event, has taken place; separating the power consumption on either side of the event into two steady states, each steady state being characterized by a profile which is a number, e.g. 256, of measurements taken at intervals throughout each power cycle (a power cycle being one complete cycle of the AC voltage); determining the transition profile by comparing the steady state profiles before and after the event; gathering data until a sufficiently large quantity of events have been recorded, e.g. one week of data logging; clustering the transition profiles and steady state profiles obtained during this data logging period; extracting closure rules from the sequence of clustered transitions and clustered steady states; determining which off transition corresponds to an on transition from the closure rules; determining which transitions corresponds to single appliances changing state or to multiple appliances simultaneous changing state from the closure rules; assigning the transitions to load changes for individual appliances; isolating from the transitions the appliances from the combined power usage signal; determining the energy used by the isolated appliances and/or the cost of the energy; presenting to the user details of the isolated appliances; and providing an assisted labeling mechanism for the user to assign a meaningful moniker to each isolated appliance; providing various graphics screens to the user that displays detail disaggregated power usage so that they have the information needed monitor their energy use; if desired, taking one or more actions to reduce the energy consumption of the monitored appliances; verifying the result; and monitoring the health of their appliances.

Process for Detecting the Change in Operational State of One or More Appliances Based on the Change in Amplitude of Circuit Power

In one embodiment, the present disclosure provides a process for detecting a change in the operational state of one or more electrical devices, loads, or appliances (collectively, “appliances”) based on a change in amplitude of circuit power. In a particular implementation, the process involves analyzing a time series of electric power or current measurements on a circuit with one or more appliances. A variable Z is calculated for each time period (t). Each time period is a full power cycle. In other implementations, the time period can be greater or less than a full power cycle, such as a fraction of a power cycle, for example, one-half a power cycle. Z is a dimensionless variable consistent with the Student's t-statistic value for calculating the probability of two populations with equal sample size and unequal variances. The Z value indicates that power is in steady state when Z's absolute value is less than a threshold or in a transition when above that threshold.

The equation for Z is:

$${Z}_{j , k} ( t ) = \frac{\begin{matrix}Avg [ P ( t - j - k ) , … , P ( t - j - 1 ) ] - \\ Avg [ P ( t + j + 1 ) , … , P ( t + j + k ) ]\end{matrix}}{\sqrt{\frac{\begin{matrix}Var [ P ( t - j - k ) , … , P ( t - j - 1 ) ] + \\ Var [ P ( t + j + 1 ) , … , P ( t + j + k ) ]\end{matrix}}{k}}}$$

where P(x) is the average power (or current) measurement calculated over a full cycle beginning at time x. Avg and Var represent the average and variance of the range of terms within the parentheses. k is the number of power measurements included in each averaging or variance period. 2*j+1 is a number of measurements in a period centered around t that are excluded from the average or variance calculations. The 2*j+1 measurements that are excluded is known as the mask period. The following example provides some representative values for use in calculating Z. However, the disclosed method is not limited to these values. For example, in other implementations, it may be beneficial for j to be 1 second (or 60 time periods) and k to be 121 time periods, or just over 2 seconds. Other values may be chosen, for example, based on how quickly an appliance turns off and on.

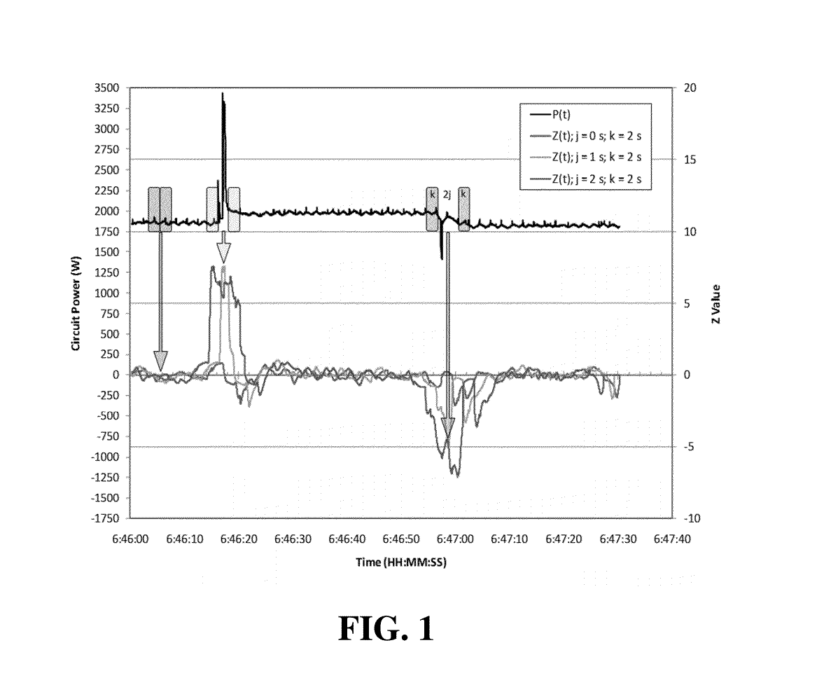

An example time series is shown in FIG. 1. In this example, the 60 Hz circuit power Pₜ is shown in black on the upper trace, with Z calculated with 3 examples of j shown on the lower trace. Here, j is expressed as a time period, with each second representing 60 power measurements. The shaded rectangles correspond to a k interval of 2 seconds (120 power measurements) used to calculate Z. The arrows indicate the Z values calculated using the P values in the corresponding colored rectangle.

In this example, using a Z threshold of 60, the “power on” transition at 6:46:18 would have been detected with Z_{1,2} and Z_{2,2}, but not with Z_{0,2}. Similarly, the “power off” transition at approximately 6:46:55 would only be detected with Z_{2,2}. The example shows how the use of a non-zero mask period (j) increases the sensitivity of this process to automatically detect power transitions in an electric circuit.

A steady state is defined as continuous period longer than j+k when the absolute value of Z is less than the Z threshold. All other times are defined as transitions. Long transition periods are typically associated with a surge of power when an appliance turns on, or when an appliance warms up slowly. After a period of time, the power settles into a steady state.

For certain monitoring applications, it can be helpful to estimate the time of power transition, T, at which an appliance is turned on or off. T is defined based on the duration of the transition period that begins at time A and ends at time B. If the transition duration (B−A) is less than 2j+2k, then T=(A+B)/2. If the transition period is longer than 2j+2k, as can occur with appliances with long turn on transitions, for a turn on event (where the power increased) T=A+j+k, i.e. close to the leading edge of the Z peak; for a turn off event T=B−j−k. Establishing the transitions points in this manner generates improved integration points for attributing total power to the appliance associated with the transition period.

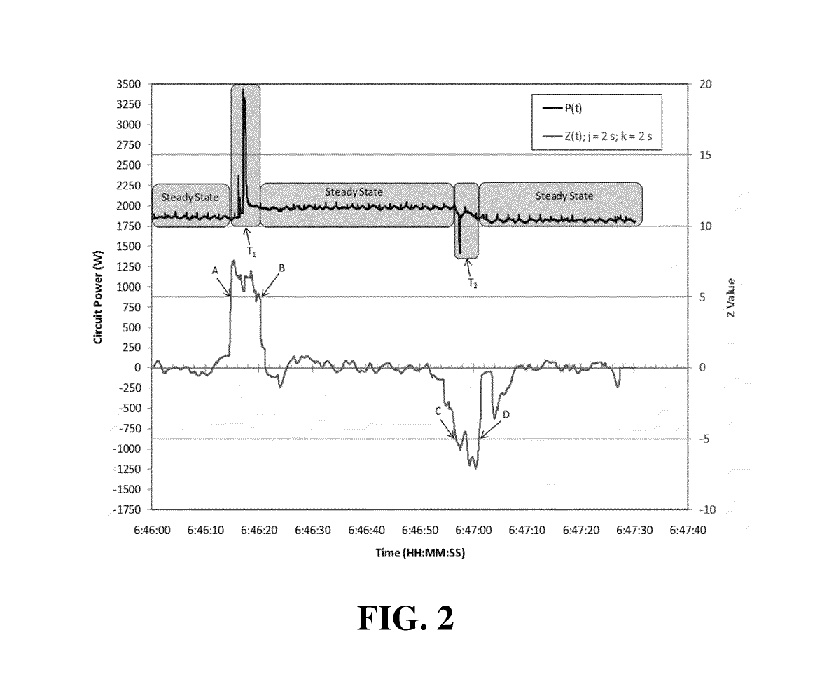

FIG. 2 illustrates an example of calculating steady state and transition periods from Z_{2,2} using the above power time series. The areas shaded in light grey correspond to the steady state periods. The dark grey areas correspond to the transitions.

T₁ is the midpoint between A (start of the first transition) and B (end of the first transition), and T₂ is the midpoint between C (start of the second transition) and D (end of the second transition).

The power signature used to identify the appliance changing state is calculated based on the difference between the consecutive steady state periods. The times T₁ and T₂ serve as integration points for determining the total power attributable to the appliance that changed state.

Some appliances have power changing transition periods longer than the duration j+k. The process is adaptive to these types of appliances in that the Z value must remain below a threshold for a minimal period, l,(l=j+k), before a new steady state is established.

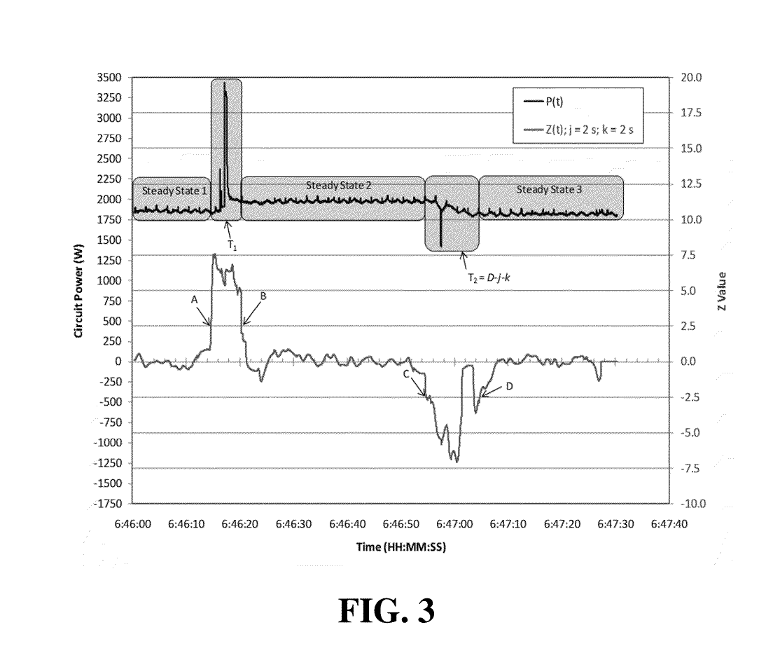

Using a lower Z threshold of 30, instead of 60, with the data shown in FIG. 3, results in a longer turn off transition period. In addition, at 6:47:01, Z remains less than the 30 threshold for only 2.1 seconds (that is less than l=j+k=4 seconds) so that the transition does not end until the second time Z crosses the −30 threshold at 6:47:04.

The following tables show the calculated average power during the steady states and the integration points using the previously described method for absolute Z threshold=30 and 60, j=2 sec, and k=2 sec. In this example, using the lower absolute Z=30, the uncertainty of the steady states are minimized and better represent the true steady state power usages of the tested appliances. In this example, the data indicates that a 117.3+/−6.2 W event turns on a T1 and that a 153.0+/−6.8 W event turns off at T2.

TABLE 1
Properties of Steady state power periods calculated with Z = 2.5 and Z = 5

| | Z = 30 | | | Z = 60 | | |
|---|---|---|---|---|---|---|
| | Average | Standard | | Average | Standard | |
| | (W) | Deviation (W) | Samples | (W) | Deviation (W) | Samples |
| Steady State 1 | 1858.6 | 14.3 | 858 | 1858.3 | 14.5 | 868 |
| Steady State 2 | 1975.9 | 15.6 | 2068 | 1976.1 | 15.6 | 2200 |
| Steady State 3 | 1822.9 | 14.1 | 1355 | 1824.6 | 16.6 | 1575 |

TABLE 2
Transient start and stop points and integration points for example power
time series

| Time Point | Z = 30 | Z = 60 |
|---|---|---|
| A | 6:46:14.261 | 6:46:14.427 |
| T1 | 6:46:17.085 | 6:46:17.069 |
| B | 6:46:19.877 | 6:46:19.744 |
| C | 6:46:54.361 | 6:46:56.427 |
| T2 | 6:47:00.327 | 6:46:58.544 |
| D | 6:47:04.327 | 6:47:00.661 |

The method above is performed in real time by adaptively buffering the windows needed to calculate Z_{j,k}k(t). Running totals of the power and squared power are used to calculate the average and variance of each windowed period. These totals are efficiently updated by subtracting the oldest sample from the buffered window and adding the next new sample. In doing so, the number of computational cycles is minimized.

The system described provides a gap spacing that is adaptive to the length of the transition period. The disclosed method separates steady state and transition periods. The disclosed method uses, at least in some implementations, a window size k and a gap size 2j. The disclosed method uses a Z threshold to determine when or if a transition has occurred.

In statistics, the method of comparing the difference of 2 populations (i.e. windowed power periods) is referred to as the sampling distribution of differences between means. The presently disclosed method is advantageous because the use of a gap between the populations helps ensure that transient behavior associated with the turning on of an appliance is not included in the calculation of the steady state signature of an appliance. In addition, the designation of the integration points as either: the T=(A+B)/2, or T=A+j+k for an increase in power, or T=B−j−k for a decrease in power, more accurately captures the true timing of when an appliance is turned on or off.

Process for Tracking the State of Electrical Appliances Using Closure Rules Linked to Steady State and Transition Power Signatures

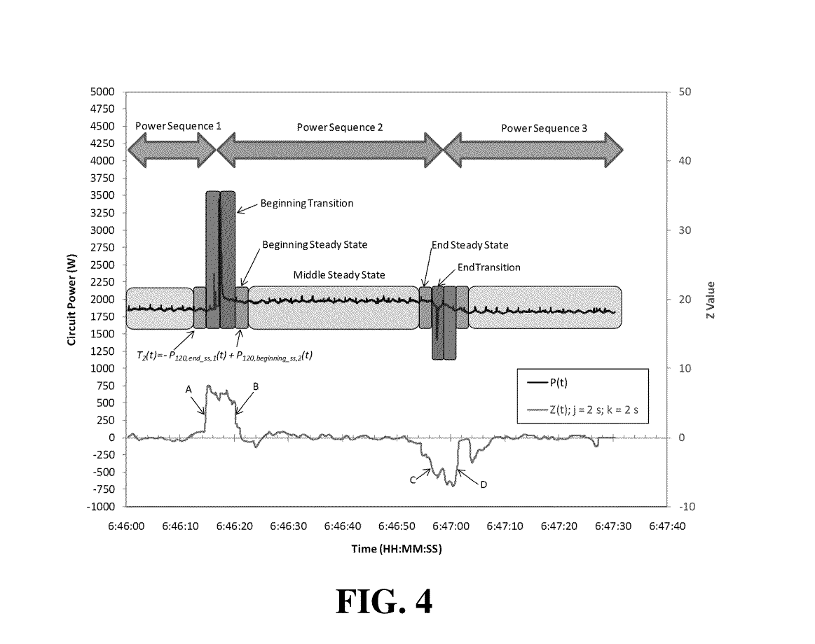

In another embodiment, the present disclosure provides a method for tracking the state of electrical appliances (as defined above) using closure rules linked to steady state and transition power signatures. This disclosed process can be used, in at least some implementations, with modified steady state signals generated from the previously described method of detecting changes in the operational stage of appliances based on changes in the amplitude of circuit power.

Whereas the previously described embodiment separates power time series in periods of transitions and steady states, this presently described embodiment further separates the steady states into three segments: a beginning steady state segment, a middle steady state segment, and an end steady state segment (FIG. 4).

In one implementation, both the beginning and end steady states have fixed segments of one second. Other segment durations may be used. The middle steady state segment is the remainder of the steady state period with the beginning and end segments removed. The entire sequence of beginning transition, beginning steady state segment, middle steady state segment, end steady state segment, and end transition is referred as a power sequence.

The three steady state segments reflect how appliances operate. The beginning steady state segment reflects how an appliance behaves immediately after it has just been turned on. The profile of an appliance during this segment is very useful in isolating appliances from each other but may not be indicative of how much power the appliance uses when it has stabilized. Generally the middle steady state segment is indicative of how much power is used while the appliance operates. As explained later, the end steady state segment is used to compare against the beginning steady state segment from the power sequence following the next transition. Other embodiments may employ more than three segments to represent how an appliance operates.

P₁₂₀ waveforms are defined at the signal representing one 60 Hz voltage cycle using the following equation:

$${P}_{120} ( t ) = \frac{i ( t ) \cdot {v}_{120}^{2} ( t )}{v ( t )}$$

Where t is the time from the beginning of the 60 Hz voltage cycle ranging from 0 to 16.7 ms, i(t) is the measured current, v(t) is the measured voltage, and v₁₂₀(t) is a sinusoidal voltage signal with a RMS value of 120 V and the same phase angle as v(t). The P₁₂₀ waveforms may be averaged over any period. The P₁₂₀ waveform is simply the conductance profile (referred to in U.S. Patent application US2009/0307178) multiplied by v₁₂₀(t). Other values of these variables can be used.

Steady state waveforms S(t) are calculated, in a specific example, as the sample weighted average waveform for the beginning, middle and end steady state segments from a single power sequence.

$$S ( t ) = \frac{\begin{matrix}{n}_{beginning\_ss} \cdot \overline{{P}_{120 , beginning\_ss} ( t )} + \\ {n}_{middle\_ss} \cdot \overline{{P}_{120 , middle , ss} ( t )} + {n}_{end\_ss} \cdot \overline{{P}_{120 , end\_ss} ( t )}\end{matrix}}{{n}_{beginning\_ss} + {n}_{middle\_ss} + {n}_{end\_ss}}$$

where nⱼ is the number of 60 Hz waveforms used to calculate the average P₁₂₀(t) during each steady state segment. The steady state waveforms can be calculated by other method without departing from the scope of the general embodiment.

Transition waveforms T(t) are calculated as the difference between the average P₁₂₀ waveforms for the beginning steady state segment of one power sequence and the end steady state segment of the immediately preceding power sequence:

Tᵢ(t)={square root over (P_{120,beginning}_{_{—}}_{ss,i}(t))}−{square root over (P_{120,end}_{_{—}}_{ss,i-1}(t))}

where the subscripts i−1 and i represents sequential power sequences. The transition waveforms can be calculated by other methods without departing from the scope of the general embodiment.

To isolate appliances, it can be helpful for the appliance monitoring, tracking, and analysis algorithm to link the separate on and off transition waveforms that belong to individual appliances. Some appliances turn on and off with transition waveforms that have opposite magnitude (i.e. T_{light}_{_{—}}ₒₙ(t) T_{light}_{_{—}}_{off}(t)=0). For such appliances, linking the on/off transitions is comparatively easy. However, for many appliances such as motors and fluorescent lights, the power on transitions and the power off transitions are asymmetric; thus this equality does not hold and a more complex algorithm may be needed to locate and pair transitions.

In one post processing implementation, a data acquisition system records the instantaneous voltage and current and generates a table of S(t) and T(t) waveforms as appliances are switched on and off. Capturing each T(t) for post-processing enables the procedure to link appropriate on and off transitions at a later time.

In some examples, post processing is not carried out by an off-line system. For example, this post processing is performed as a parallel task while real-time data is being collected by the data acquisition system. The post processing aspect of this task is that it cannot be performed until sufficient transition data has been logged by the data acquisition system.

At intervals, such as regular intervals, a clustering algorithm is applied to both tables of S(t) and T(t) waveforms. An appropriate number of steady state clusters are obtained from the cluster agglomeration table based on a threshold cluster similarity or dissimilarity metric (e.g. Euclidian distance, error sum-of-squares, correlation coefficient, etc.).

According to present embodiment, members of the same S(t) cluster represent times when the same set of appliances are either on or off.

According to the embodiment, when two steady states, Sⱼ(t) and Sⱼ₊ₖ(t)), belong to the same steady state cluster, then the sequence of Tⱼ₊₁(t), . . . , Tⱼ₊ₖ(t) represents a complete (on-off, or off-on) cycling of all appliances that changed state between Sⱼ(t) and Sⱼ₊ₖ(t)). This is referred to as closure and enables asymmetric power on and power off transitions to be linked together even though their waveforms are dissimilar. Prior analysis methods typically require that on and off transition must be of opposite magnitude in order to establish a match, and are thus inadequate for many appliances.

Closure rules are extracted from the data set. For each steady state in a particular steady state cluster, the transition sequence to the next steady state in the same steady cluster generates a closure rule. Transitions sequences need not be unique; only one example of each unique transition sequence needs to be included in the complete set of closure rules. The number of transitions between two steady states that are members of the same cluster may range from one to one less than the total number of steady states (i.e. z−1). Furthermore, the number of rules that may be extracted from a dataset is the total number of steady states observed minus the total number of steady state clusters (i.e. z−y).

The length of a closure rule is the number of transitions in that rule. Closure rules of length one represent relatively small power changes that occur and do not change the classification of the steady state. They typically do not provide useful information in linking the on/off transition of appliances. In at least some cases, rules of length one can be discarded.

Rules of length two generally represent the cycling of one appliance. In such a rule, the two transitions represent the on/off (or off/on) transitions for single appliances. Those transitions can now be linked. It is possible that a rule of size 2 can represent two, or more, appliances cycling simultaneously. In typical cases, this rule alone cannot distinguish between single and multiple appliances.

Transitions of length three can represent “multi-match” scenarios as described below in the embodiment entitled Method to resolve the operational state of an appliance by matching multiple appliances to a single event. Rules longer than 3 may represent state changes of more complex appliances, but they are also likely to represent the simple cycling sequence of several appliances: e.g. appliance A turns on, appliance B turns on, appliance A turns off, appliance B turns off.

To extract information from these longer rules, the procedure may employ an elimination mechanism. Whereas Tᵢ(t) may represent the waveform centroid of a transition, the term xᵢ refers to the clustered transition but has no relevant quantitative value. The xᵢ terms are used to express the closure rules using linear algebraic conventions.

Given a total of m transition clusters, each closure rule can be expressed as:

$${\sum }_{i = 1}^{m} {a}_{i} {x}_{i} = 0$$

where the coefficient aᵢ represents how many times the transition cluster xᵢ is observed in the closure rule. An entire dataset with y closure rules that can be expressed in matrix form as Ax=0 where A is a matrix with m columns and y rows. A simple closure rule xᵢ+xⱼ=0, provides the relationship that transition xᵢ is the inverse of transition xⱼ.

A judicious elimination process is used to identify these relationships without eliminating transitions related to real appliances. This process can include one or more of the following, or additional components:
1) Eliminating rules, such as all rules, that occur nested within other rules. For examples if the rule xᵢ₊₁+xᵢ₊₂=0 follows the rule xᵢ+xᵢ₊₁+xᵢ₊₂+xᵢ₊₃=0, then the first rule is eliminated from the second to leave only the two rules: xᵢ₊₁+xᵢ₊₂=0 and xᵢ+xᵢ₊₃=0.
2) Grouping identical rules and sorting unique rules by decreasing frequency of occurrence.
3) Use rules of length 2 to reduce rules of larger length starting with the most frequently observed rule of length 2. In some cases the length 2 rule may occur multiple times in a larger rule and can be removed multiple times, i.e. given the length 2 rule of xᵢ₊₁+xᵢ₊₂, the length 7 rule of xᵢ+2 xᵢ₊₁+3 xᵢ₊₂+xᵢ₊₃ would be reduced to xᵢ+xᵢ₊₂+xᵢ₊₃. With each elimination, the frequency count of the rule of length two increases by one.
4) After eliminating the rule of length 2 from all other rules, the rule of length 2 is moved into the used rule set.
5) Steps 2-5 are repeated using the next most frequent rule of length two from the regrouped and sorted rule list. This continues until there are no remaining rules of length 2.
6) The most frequently occurring rule in the used rule set is assigned to Appliance 1. The transition associated with the positive power step is associated with the turning on of the appliance (+Appliance ID) whereas the negative power transition is associated with turning off the appliance (−Appliance ID).
7) The next rule of length 2 in the used rule set is compared with the transition members of each Appliance ID. If a transition is found that is already assigned to an Appliance ID, then both transitions in the rule are assigned to the corresponding positive or negative Appliance ID. If no match is found, i.e. neither transition has previously been assigned, the two transitions in the rule are assigned to the next Appliance ID.
8) Step 7 is repeated until all of the transitions of rules of length 2 are assigned to Appliances. Each transition is assigned to one and only one signed Appliance ID. This assignment process accommodates appliances that turn on and off with different transition signatures.
9) All remaining rules of length 1 in the grouped and sorted rule set are assigned to the null Appliance ID, Appliance 0, and moved to the used rule set. These rules correspond to small power transitions that typically cannot be reliably associated with appliance transitions.
10) The remaining rules (of length 3 or more) in the grouped and sorted rule set are renamed as the remaining long rule set.
11) Beginning with the highest frequency rule within the remaining long rule set, each transition is searched for the first transition that is not already assigned to an Appliance ID. Any prior assignment is due to rules in the used rule set. If there is more than one unassigned transition in a rule, that rule is skipped and the next rule is searched. When an unassigned transition is found and all other transitions in the rule have already been assigned, then the one unassigned transition is assigned to the combination of opposite signed Appliances associated with the assigned transitions in the rule. This assignment process accommodates transitions where more than one appliance changes state simultaneously.
12) The newly assigned rule is then moved to the used rule set.
13) Steps 11 and 12 are repeated until only rules with 2 or more unassigned transitions remain.
14) All unassigned transition IDs are then subjected to the multi-match analysis described below. Unassigned transition profiles are matched to one or more assigned-transition profiles and the corresponding set of appliances are assigned to the unassigned transition ID. If no match is made based on the threshold cluster similarity or dissimilarity metric mentioned above, then the transition is assumed to occur infrequently and assigned to the null appliance.

The outcome of these steps is an appliance assignment table for all transition clusters which can be used to generate a time series of appliance state changes. This time series is then used to determine the operational state of each isolated appliance.

Anomalies in the time series, such as an appliance turning on and then turning on again before being turned off, can be detected. These anomalies can be used to locate periods where the algorithm has missed an event, i.e. a change in state for that appliance. The change in state can be missed due to e.g. a large number of appliances changing state at one time, or may be due to the presence of a large amount of noise in the data. Between the anomalies more computationally complex algorithms can be used to find the missed event. The period of time during which the missed event occurred is bounded by the two anomalous events. Given this bounded period and knowledge of what type of event was missed i.e. the specific on/off transition for the particular appliance, more computational complex algorithms can be used to search for that event during the bounded period. If the missed event cannot be found, then one of the anomalous events will be discarded. In the case of an anomalous sequence of two on events, the first on event is discarded; for the anomalous sequence of two off events, the second off event is discarded.

The presently described embodiment can be advantageous, such as having greater accuracy, than systems that only determine appliance state by the step transitions. The presently described embodiment can also be used to more accurately detect the situation in which multiple appliances change state during a single event.

Method to Resolve the Operational State of an Appliance by Matching Multiple Appliances to a Single Event

In some embodiments, a method to resolve the operational stage of an appliance includes matching multiple appliances to a single event, sometimes referred to as “multimatch” or a “combo-event”. The method can be applied to the field of Non-Intrusive Appliance Load Monitoring (NIALM), such as decomposing a power meter signal into constituent loads to segregate and identify energy consumption associated with each individual load on the circuit.

Some NIALM methods involve three steps: (1) identifying when an appliance has turned off or on using a net change detector, (2) using a subtractor to compare the difference between two steady state periods in order to obtain a characteristic signature of the appliance, and (3) grouping together the list of signatures and using a cluster algorithm to determine the time series of each appliance's state. This approach is structured to be performed after a period of sampling and typically does not lend itself to real time data analysis. However, the analysis can be done as a background task to real time data logging and once the results of the analysis is available it can be used to process logged data in real time.

The presently disclosed embodiment can be advantageous because it provides a method that can identify the operational state of multiple appliances when more than one appliance turns on or off at the same time. In addition, this embodiment provides a second method that can be used to correct the inferred operational state of an appliance when a device is found to transition into an invalid state.

When initially connected to the AC mains to monitor voltage and current signals, the present embodiment has no a-priori knowledge of the number, types, or initial state (on/off), of the appliances on the circuit. A processor isolates power transitions on the monitored circuit associated with one or more appliances turning on or off. In some cases, all power transitions are isolated. In other cases, only a portion of the power transitions are isolated. As the state of one or more appliance change, an event is generated and the disclosed embodiment is able to define the power signature of the transition from one state to the next.

The signature is compared to a library of signatures already isolated. One or more, such as a weighted combination, of goodness of fit indicators (i.e. correlation coefficient, slope, intercept, RMS error, residual) are used to confirm and select the best match with signatures in the library.

If no match is found, the signature is added to the library of signatures as a new unconfirmed appliance. Unconfirmed appliances are appliances that have previously not been seen or are appliances that have previously been seen but are now in an inconsistent state. Additionally, an unconfirmed appliance might be a combination of two or more simultaneously changing (elemental) appliances, and these elemental appliances may or may not have been previously seen.

A new unconfirmed appliance may be further subjected to a secondary matching of multiple combinations of other unconfirmed library entries. Candidate combinations are composed from each possible permutation of positive and negative transitions of two or more other unconfirmed appliances.

For example, if the library contains 3 unconfirmed signatures, A, B, and C, and a new signature D is added as another unconfirmed appliance, D is compared with each combination of A, B, and C in both the positive and negative forms. In this simple case 20 combinations exist:

$$D = \{ A , B , C \} , \{ - A , B , C \} , \{ A , - B , C \} , \{ A , B , - C \} , \{ - A , - B , C \} , \{ A , - B , - C \} , \{ - A , B , - C \} , \{ - A , - B , - C \} , \{ A , B \} , \{ A , C \} , \{ B , C \} , \{ - A , B \} , \{ - A , C \} , \{ - B , C \} , \{ A , - B \} , \{ A , - C \} , \{ B , - C \} , \{ - A , - B \} , \{ - A , - C \} , or \{ - B , - C \} .$$

The combinations are first tested to ensure the combined power matches D within a predefined relative and absolute tolerance. The subset of solutions that meet these criteria are subjected to the more computationally expensive goodness of fit tests. To minimize computing expense, combinations are limited to 6 elements or less, in some implementations.

When one or more combination meets the weighted goodness of fit tests, the candidates are optionally further examined to distinguish the signature that is the combination and the signatures that are elements of the combination corresponding to individual appliances.

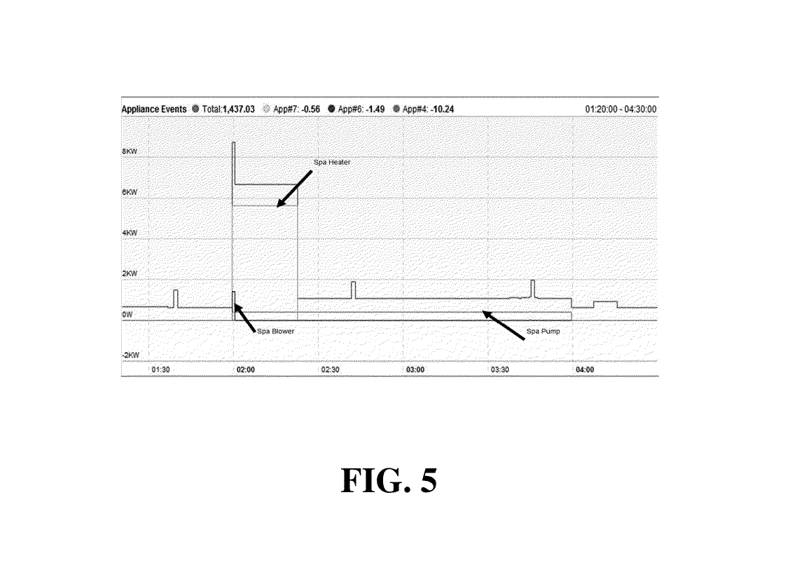

As an example, FIG. 5 illustrates a sequence of four events corresponding to the cycling of components in a hot tub. On the first event (A), three components (heater, pump, and blower) turn on. On the second event, the blower turns off (−B). On the third event, the heater turns off (−C). At this point, no signatures have been matched in the library. On the fourth event, the pump turns off (−D). At this point a goodness of fit match is now found in the list of possible combinations such that: D={A,−B,−C}.

The existence of a match is typically insufficient to determine which signature is the combination and which are elements. Analysis of the propagation of signature uncertainty may be used to distinguish the combination signature from the signatures of the elements.

For the linear combination f of n variables a₁x₁, . . . , aₙxₙ, where:

$$f = {\sum }_{i}^{n} {a}_{i} {x}_{i}$$

the variance of f is defined as:

$${σ}_{f}^{2} = {\sum }_{i}^{n} {a}_{i}^{2} {σ}_{i}^{2} + {\sum }_{i}^{n} {\sum }_{j ( j \neq i )}^{n} {a}_{i} {a}_{j} {ρ}_{ij} {σ}_{i} {σ}_{j}$$

Where ρᵢⱼ is the correlation coefficient between xᵢ and xⱼ. When the variables x are uncorrelated (as would be expected for the power signatures of separate appliances), the variance of f reduces to:

$${σ}_{f}^{2} = {\sum }_{i}^{n} {a}_{i}^{2} {σ}_{i}^{2} .$$

Therefore, the variance of the combination signature is by definition the sum of the variances of the elements. For the above example, relating to the components of the hot tub, the goodness of fit match indicates that the signatures:

D=A−B−C.

However, the corresponding equation for the variance is not true:

σ_{D}²≠σ_{A}²+(—1)²σ_{B}²+(−1)²σ_{C}²

By systematically reordering the terms in the combination equation, the correct arrangement:

A=B+C+D

With the combined signature on one side of the equation and the elements on the other also satisfies the combined variance equation:

σ_{A}²=σ_{B}²+σ_{C}²+σ_{D}²

This novel ANOVA method is equally effective for distinguishing elements from combinations in events when one or more element turns on and one or more element turns off simultaneously. It can also be used in conjunction with the closure rules of size 3 or more to determine which of the transitions is the combination transition.

Once the elements have been quantitatively distinguished from the combination, the event related to the combined signature is replaced with an event for each of the elemental appliances as shown in FIG. 5.

The combination signature remains in the library with pointers indicating that a match on this signature represents the change of state of the three components: blower, heater, and pump. When the combination event occurs again, it is immediately matched with the prior combination signature and used to record a state change of the three elemental appliances.

After an unconfirmed appliance has been seen to change states in a consistent manner (i.e. first on then off, or first off then on), the unconfirmed label is removed from the library entry.

An inconsistent change of state exists when an appliance that was previously considered to be in the on state, is seen to turn on again without first turning off. Such a situation results in an inconsistent event for an appliance. At this point the appliance is relabeled as unconfirmed.

Process for Itemizing Electricity Consumption to Specific Loads

The presently disclosed embodiment provides a process for itemizing electricity consumption to specific loads. In at least one implementation, the disclosed embodiment uses modified steady state signals generated from the previously described embodiment of a process for detecting the change in the operational state of one or more appliances based on the change in amplitude of circuit power and the previously described embodiment of a process for tracking the state of electrical appliances using closure rules linked to steady state and transition power signature.

The load disaggregation algorithm may run in two modes: post process analysis and real time analysis. In post process analysis, the data is analyzed from a period of time such that when a cluster program is applied to the steady states and transitions, multiple instances of steady states are grouped into common clusters. In real time mode, each new steady state and transition are compared with existing clusters. If they are sufficiently close, they are assigned to an existing cluster and the cluster centroid is recalculated. If they have a Euclidian distance sufficiently larger than any existing cluster, then they become the centroid of a new cluster. In at least certain implementations of both cases, every measured steady state and transition signature is assigned to clusters even if the cluster has only one member.

Each steady state period is separated by a transition event. A Transition Table can be maintained in real time with the fields: [Steady State IDₛₜₐᵣₜ, Transition ID, Steady State ID_{End}] where the fields are the Steady State and Transition Signature cluster IDs.

An example system to illustrate the analysis is given in the state transition table shown in Table 3.

TABLE 3
Transition table mapping the start and end Steady States for each
Transition.

| Steady State Start ID | Transition ID | Steady State End ID |
|---|---|---|
| 0 | 1 | 1 |
| 0 | 3 | 2 |
| 0 | 5 | 3 |
| 1 | 2 | 0 |
| 1 | 3 | 3 |
| 2 | 4 | 0 |
| 2 | 1 | 3 |
| 3 | 6 | 0 |
| 3 | 4 | 1 |
| 3 | 2 | 2 |

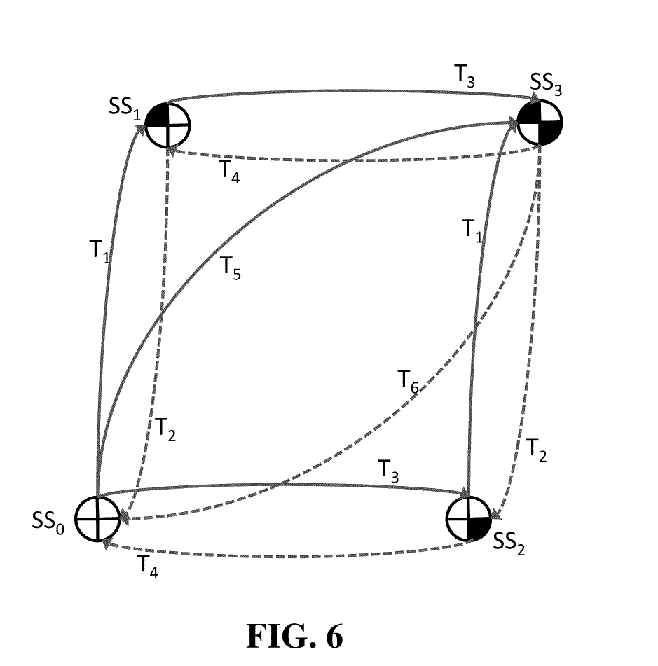

The state transition table is what is used by the algorithm; however a state diagram may be easier for a human to follow. FIG. 6 presents the state diagram for the system specified in transition Table 3. The circles denote unique steady states and lines represent transitions. The state diagram, specifically the state of each load at each Steady State, is what is to be derived by the algorithm from the list of Steady State, Transition, Steady State tuples.

A closure is defined when a sequence of transitions leads from a particular Steady State back to the same Steady State. The sequence of transitions, and intermediate State States, that are traversed is known as a Closure Rule (CR). The length of a CR is the number of transitions that occur. CRs are the shortest possible unique transitions sequences for returning to a state, without repeating a state apart from the initial Steady State.

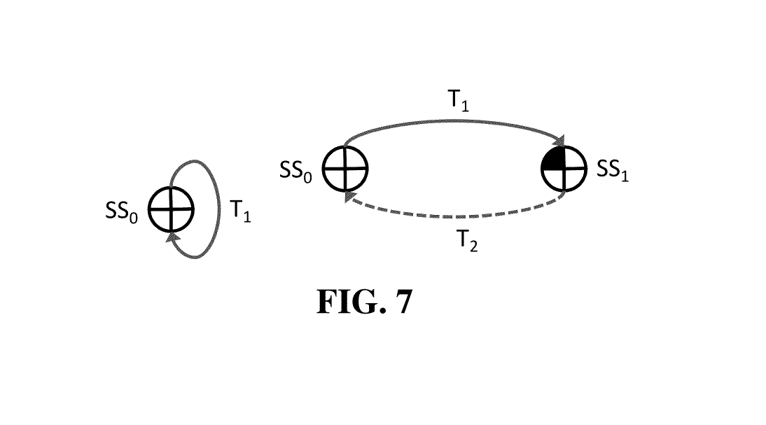

Generally short CRs are desirable in that they can be directly used to infer what loads represent the turning on/off of an appliance. Closure rules of length 1, depicted in the left panel of FIG. 7, typically represent very small transitions that do not cause a change in the clustered steady state. These Transition IDs may be flagged as trivial or Null to indicate that any associated loads may be below detectable limits.

CRs of length 2 are typically the most useful, since typically the two transitions in the closure rule directly translate into an “on” transition and an “off” transition as depicted in the right panel of FIG. 7. In FIG. 7, the convention used is that an “on” transition is represented by an odd transition index, while an “off” transition is represented by an even transition index.

A Steady State is known as a Defined Steady State when the state of all loads, either on or off, are known for that Steady State. The number of loads in the system is initially unknown, though a maximum of “n” loads can be assumed. An individual load is represented by the load ID Lᵢ where ᵢ is one of indices 1 . . . n. Each Steady State represents a combination of each of the loads being on +Lᵢ or being off −Lᵢ. For the most part, Steady States are usually unique in terms of the combinations of individual loads. However as discussed later, due to variations in the operational states of appliances, some Steady States may have duplicate load combinations.

The Set of Defined Steady States, (SDSS), represents all Steady States which have so far been defined by the analysis in that the on/off state of each load is known for each state. The eventual goal is to have all Steady States in the SDSS. CRs can be used on the existing Steady States in the SDSS to derive new Defined Steady States. Initially the SDSS contains just one entry corresponding to the Steady State that uses the least amount of power. The assumption for this starting steady state, SS₀, is that all loads represented by that state, L₁ . . . Lₙ are zero. At this point the SDSS is represented by Table 4.

TABLE 4
Initial SDSS starting from SS₀.

| Steady State ID | L₁ . . . Lₙ |
|---|---|
| 0 | 0 . . . 0 |

Starting with SS₀, as each state is added to the SDSS, the set of CRs of size 2 which includes the new DSS is found. These CRs determine the next steady state and define what load transition occurred. This results in new DSS being generated which in turn will be added to the SDSS. For the system in FIG. 6, when SS₀ is first added to the SDSS, the following CRs are obtained:

TABLE 5
Closure Rules of length 2 from SS₀

| Closure Rule | Transition 1 | Transition 2 | Load ID |
|---|---|---|---|
| CR₁ | 1 | 2 | L₁ |
| CR₂ | 3 | 4 | L₂ |
| CR₃ | 5 | 6 | L₃ |

The load IDs, Lᵢ are systematically assigned with increasing indices to each CR. In this example L₁ and L₂ correspond to one load turning on/off, however, L₃ corresponds to two loads simultaneously turning on/off. The initial assumption that CRs CR₁ . . . CR₃ only cause a single load to change in each newly visited state, SS₁, SS₂ & SS₃, allows the newly visited states to be defined. [At this stage in the analysis, i.e. only considering the CRs of size 2 from SS₀, there is typically not yet enough information to determine that L₃ is a combination of two loads.] Using this assumption the following SDSS is generated.

TABLE 6
SDSS after closures rules of length 2, have been applied to the
previous SDSS

| Steady State ID | L₁ | L₂ | L₃ | L₄ . . . Lₙ |
|---|---|---|---|---|
| 0 | 0 | 0 | 0 | 0 . . . 0 |
| 1 | 1 | 0 | 0 | 0 . . . 0 |
| 2 | 0 | 1 | 0 | 0 . . . 0 |
| 3 | 0 | 0 | 1 | 0 . . . 0 |

Next, for the newly added Steady States, SS₁, SS₂ & SS₃, closure rules of size 2 are examined.

TABLE 7
Closure Rules of length 2 from SS₁, SS₂ & SS₃

| Closure | | | | Number of Undefined |
|---|---|---|---|---|
| Rule | Transition 1 | Transition 2 | Load ID | SS visited |
| CR₄ | 2 | 1 | L₄ | 0 |
| CR₅ | 4 | 3 | L₅ | 0 |
| CR₆ | 2 | 1 | L₆ | 0 |
| CR₇ | 4 | 3 | L₇ | 0 |
| CR₈ | 2 | 1 | L₈ | 0 |
| CR₉ | 4 | 3 | L₉ | 0 |
| CR₁₀ | 6 | 5 | L₁₀ | 0 |

Though there are seven new CRs, none of them provide any additional information from what had been previously determined. A CR of size 2 is considered useful if at least one undefined Steady State is encountered. If a CR is not useful it can be discarded and both its rule number and Load ID number can be reused. Since none of the seven CRs are useful, no additions could be made to the SDSS.

Since no additions were made to the SDSS the analysis now considers CRs of size 3 for the Steady States in the SDSS. The Steady States in the SDSS are evaluated in the order in which they were placed in the SDSS, i.e. initially CRs of size 3 are considered only for SS₀, with CRs of size 3 considered for SS₁, SS₂ & SS₃ later.

TABLE 8
Closure Rules of length 3 from SS₀

| | | | | | Number |
|---|---|---|---|---|---|
| | | | | | of |
| | Transi- | Transi- | Transi- | | Undefined |
| Closure Rule | tion 1 | tion 2 | tion 3 | Load IDs | SS visited |
| CR₄ | 1 | 3 | 6 | L₄, L₅, -L₆ | 0 |
| CR₅ | 3 | 1 | 6 | L₇, L₈, -L₉ | 0 |
| CR₆ | 5 | 2 | 4 | L₁₀, -L₁₁, -L₁₂ | 0 |
| CR₇ | 5 | 4 | 2 | L₁₃, -L₁₄, -L₁₅ | 0 |

For each CR three load IDs are needed, representing the load which changed with each of the three transitions. As seen earlier, CRs of size two only required one load ID, as the two transitions in the CR directly correspond to the positive and negative version of that load. For transition and Steady State combinations previously seen in the SDSS the new load IDs can be replaced with the existing load IDs. In the above example, transition T₁ goes from SS₀ to SS₁ with the corresponding load ID L₄, however earlier this same SS₀->T₁->SS₁ sequence was represented by load ID L₁. Substitution for all previously existing load IDs yields the following table.

TABLE 9
Closure Rules of length 3 from SS₀

| | | | | | Number of |
|---|---|---|---|---|---|
| Closure | Transi- | | | | Undefined |
| Rule | tion 1 | Transition 2 | Transition 3 | Load IDs | SS visited |
| CR₄ | 1 | 3 | 6 | L₁, L₂, -L₃ | 0 |
| CR₅ | 3 | 1 | 6 | L₂, L₁, -L₃ | 0 |
| CR₆ | 5 | 2 | 4 | L₃, -L₁, -L₂ | 0 |
| CR₇ | 5 | 4 | 2 | L₃, -L₂, -L₁ | 0 |

CRs of size three fall into three categories based on the number of undefined Steady States that are visited, i.e. 0, 1 or 2; and each category needs to be processed separately. In the above example no new steady states were visited. Unlike the case with CRs of size 2 in which CRs that had no new Steady States are not useful, CRs of size 3 in which no new Steady States are visited can be useful as they can provide information which can be used to determine that loads previously determined by CRs of length 2 are actually combination loads. For each CR the combined effect for all the loads involved must equal zero. Thus CR₄ yields the load ID relationship L₁+L₂−L₃=0. Arranging the load IDs to be all positive yields the relationship that L₃=L₁+L₂, i.e. Load ID L₃ is in fact a combination of the smaller loads L₁ and L₂. Load ID L₃ is then replaced in the SDSS with a combination of load ID L₁ and L₂, giving:

TABLE 10
Substituting L₃ = L₁ + L₂ in the SDSS

| Steady State ID | L₁ | L₂ | L₃ | L₄ . . . Lₙ |
|---|---|---|---|---|
| 0 | 0 | 0 | 0 | 0 . . . 0 |
| 1 | 1 | 0 | 0 | 0 . . . 0 |
| 2 | 0 | 1 | 0 | 0 . . . 0 |
| 3 | 1 | 1 | 0 | 0 . . . 0 |

Substitution for Load ID L₃ in this manner allows for L₃ to be dropped from the table, giving

TABLE 11
Dropping the substitute L₃ from the SDSS

| Steady State ID | L₁ | L₂ | L₄ . . . Lₙ |
|---|---|---|---|
| 0 | 0 | 0 | 0 . . . 0 |
| 1 | 1 | 0 | 0 . . . 0 |
| 2 | 0 | 1 | 0 . . . 0 |
| 3 | 1 | 1 | 0 . . . 0 |

A load ID dropped in this manner can also be reused. CR₅, CR₆, and CR₇ also yields the relationship that L₃=L₁+L₂, while consistent it provides no additional information as load L₃ has already been substituted.

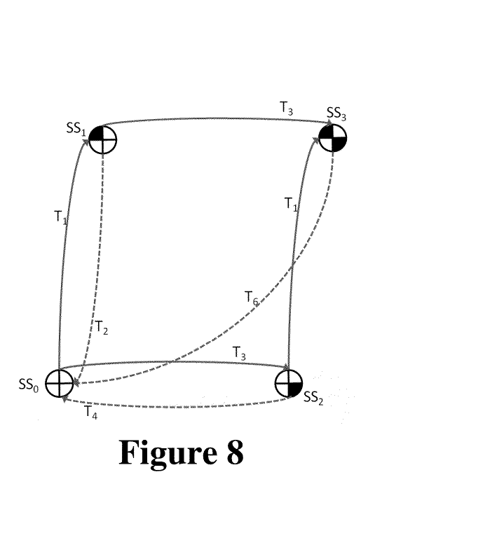

As mentioned earlier CRs of size 3 and originating from DSSs may fall into three categories based on the number of undefined Steady States that are visited, i.e. 0, 1 or 2. The CRs of size 3 in the above example yields no undefined Steady States however a modification to the state diagram, shown in FIG. 8, yields CRs of size three with the undefined Steady State 3.

For this system the SDSS obtained after evaluation all CRs of length 2 is:

TABLE 12
SDSS after closures rules of length 2, have been applied

| Steady State ID | L₁ | L₂ | L₃ . . . Lₙ |
|---|---|---|---|
| 0 | 0 | 0 | 0 . . . 0 |
| 1 | 1 | 0 | 0 . . . 0 |
| 2 | 0 | 1 | 0 . . . 0 |

TABLE 13
Closure Rules of length 3 from SS₀

| | | | | | Number of |
|---|---|---|---|---|---|
| Closure | Transi- | | | | Undefined |
| Rule | tion 1 | Transition 2 | Transition 3 | Load IDs | SS visited |
| CR₃ | 1 | 3 | 6 | L₁, L₂, -L₃ | 1 |
| CR₄ | 3 | 1 | 6 | L₂, L₁, -L₃ | 1 |

For CR₃ there is one new undefined Stead State visited, i.e. SS₃. This state is reached from SS₁ via transition T₃. SS₁ is defined and T₃ is associated with load ID L₂ thus allowing SS₃ to be a Defined Steady State and can be added to the SDSS:

TABLE 14
Adding SS₃ by evaluating T₃ from SS₁ in CR₄

| Steady State ID | L₁ | L₂ | L₄ . . . Lₙ |
|---|---|---|---|
| 0 | 0 | 0 | 0 . . . 0 |
| 1 | 1 | 0 | 0 . . . 0 |
| 2 | 0 | 1 | 0 . . . 0 |
| 3 | 1 | 1 | 0 . . . 0 |

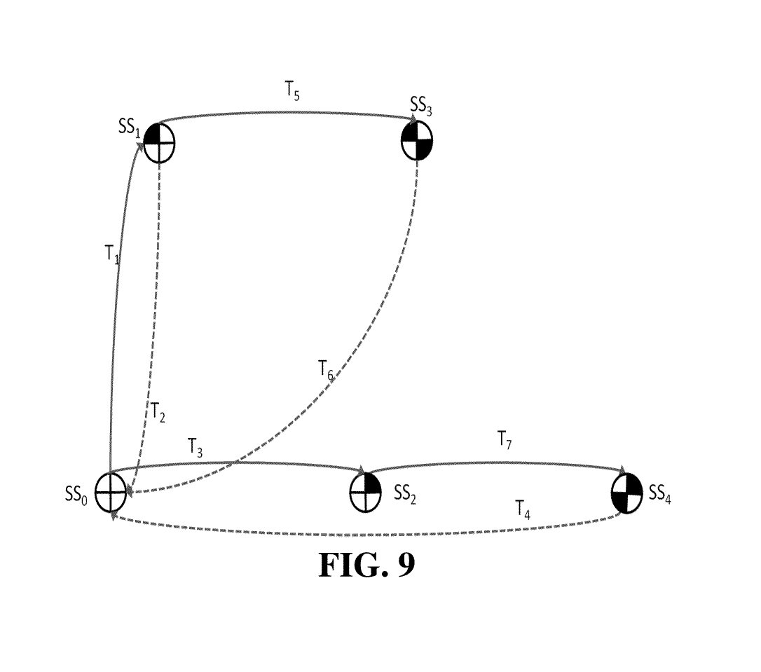

FIG. 9 illustrates two different CR of size 3 scenarios. The resulting CR table is shown in Table 15.

TABLE 15
Closure Rules of length 3 from SS₀ in FIG. 9

| | | | | | Number of |
|---|---|---|---|---|---|
| Closure | Transi- | | | | Undefined |
| Rule | tion 1 | Transition 2 | Transition 3 | Load IDs | SS visited |
| CR₂ | 1 | 5 | 6 | L₁, L₂, -L₃ | 1 |
| CR₃ | 3 | 7 | 4 | L₄, L₅, -L₆ | 2 |

Initially CR₂ in Table 15 seems similar to CR₃ in Table 13 in that only one undefined Steady State has been visited. However in this case the load ID sequence L₁, L₂, −L₃ contains 2 loads that have not been seen before: L₂ and −L₃. Given closure, the relationship L₃=L₁+L₂ can be extracted thus allowing state SS₃ to be defined.

TABLE 16
Adding SS₃ from CR₂

| Steady State ID | L₁ | L₂ | L₄ . . . Lₙ |
|---|---|---|---|
| 0 | 0 | 0 | 0 . . . 0 |
| 1 | 1 | 0 | 0 . . . 0 |
| 3 | 1 | 1 | 0 . . . 0 |

CR₃ has two new Steady States SS₂ and SS₄, and all three of the load IDs have not been seen before. However the relationship L₆=L₄+L₅ can be extracted allowing SS₂ and SS₄ to be added to the SDSS:

TABLE 17
Adding SS₃ from CR₂

| Steady State ID | L₁ | L₂ | L₄ | L₅ | L₆ . . . Lₙ |
|---|---|---|---|---|---|
| 0 | 0 | 0 | 0 | 0 | 0 . . . 0 |
| 1 | 1 | 0 | 0 | 0 | 0 . . . 0 |
| 3 | 1 | 1 | 0 | 0 | 0 . . . 0 |
| 2 | 0 | 0 | 1 | 0 | 0 . . . 0 |
| 4 | 0 | 0 | 1 | 1 | 0 . . . 0 |

With each Steady State added to the SDSS the algorithm recursively considers if the new Steady State has any CRs of size 2. If not, the algorithm continues to evaluate CRs of size 3. This continues until all Steady States are in the SDSS. In some situations CRs of size 4 or larger need to be applied in order to include all Steady States in the SDSS. These rules follow the same logic as those applied to rules of size 3.

Different Transition Signatures for the State Change of the Same Load

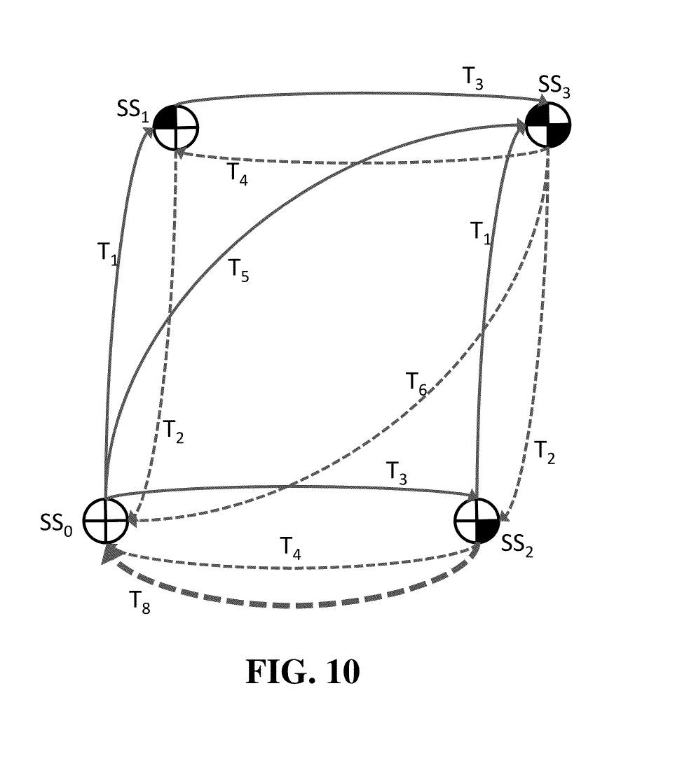

Some appliances turn on and require a period of time from seconds to minutes to reach their stable power usage. If these appliances turn off before they reach their stable state, then the magnitude of the off transition may substantially differ from that observed with a longer operation cycle. On the state diagram shown in FIG. 10, this is represented as Transition 8 (in bold) connecting Steady States 2 and 0 adjacent to Transition 4.

In this case, the algorithm identifies another CR of size 2 for newly released load label L₃ linking transitions T₃ to T₈ as shown in the Closure Rule Table 18.

TABLE 18
Closure Rules of length 2 from SS0 from FIG. 10.

| Closure Rule | Transition 1 | Transition 2 | Load ID |
|---|---|---|---|
| CR₁ | 1 | 2 | L₁ |
| CR₂ | 3 | 4 | L₂ |
| CR₃ | 5 | 6 | L₁ + L₂ |
| CR₄ | 3 | 8 | L₃ |

as depicted in the Steady State Load Table below:

TABLE 19
Revised Steady State Load Table where the operation state
of each load is known for each state.

| Steady State ID | L₁ | L₂ | L₃ |
|---|---|---|---|
| 0 | 0 | 0 | 0 |
| 1 | 1 | 0 | 0 |
| 2 | 0 | 1 | 0 |
| 3 | 1 | 1 | 0 |
| 2 | 0 | 0 | 1 |

There are two records for Steady State 2, with one indicating that only L₂ is on and the other indicating that only load L₃ is on. The conclusion from these redundant records describing the same steady state is that L₂=L₃ but are characterized by separate combinations of transitions. This finding may be retained by renaming the corresponding L₃ in the Closure Rule Table as L₂.

Twin Identification

On many circuits, there are frequently instances where two appliances have identical transition signatures (e.g. banks of identical lights, two computer monitors, etc.). Although these loads cannot typically be distinguished just using closure rules, multiple instances are represented in Steady State Load table with entries greater than one. This information is valuable since although the user may not know exactly which load is actuated, energy can be allocated to a group of similar loads.

Multistate Appliance Isolation

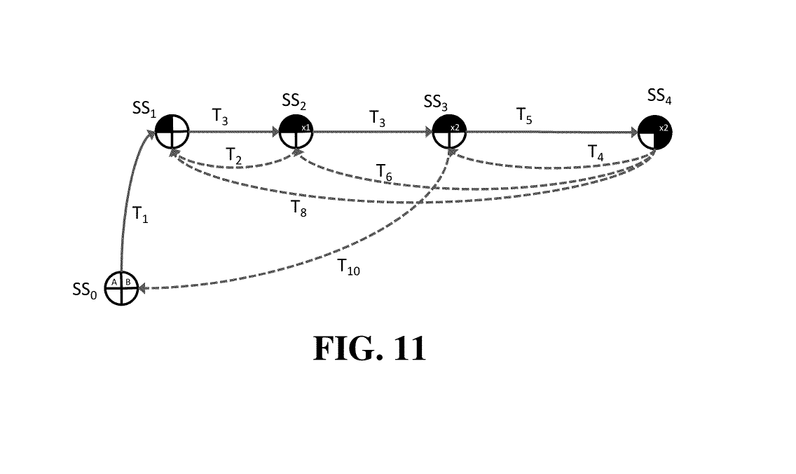

Many appliances have multiple states of operation that are interrelated. For example a furnace blower may only operate when an electrical circuit panel is energized. Alternatively, a ceiling fan may have four speed settings. These types of loads pose a challenge since they do not cycle as a simple two state load. Complex loads can be characterized using the scheme described above. FIG. 11 illustrates a load that turns on from SS₀ to SS₁ and then moves between SS₁ through SS₄ before turning off at SS₃. (Note: the Steady State ID and Transition IDs do not correspond to the previous examples.) Systematically applying CRs of increasing size (i.e., 2, 3, 4, etc.) will enable the appliance below to be deconstructed in to a variety of sub loads that may appear multiple times.

Over a long enough period of random cycling, the system may behave such that each of the change in state is represented as a single isolated load with a Steady State Load table resembling Table 20A.

TABLE 20A
Revised Steady State Load Table where the operation
state of each load is known for each state.

| Steady State ID | L₁ | L₂ | L₃ |
|---|---|---|---|
| 0 | 0 | 0 | 0 |
| 1 | 1 | 0 | 0 |
| 2 | 1 | 1 | 0 |
| 3 | 1 | 2 | 0 |
| 4 | 1 | 2 | 1 |

A feature that links these loads together is the fact that L₂ and L₃ are on only when L₁ is on. In some cases this may be coincidental and the relationship may be broken after a period of time with random appliance cycling, but in others (e.g. a plasma TV with a large base load and numerous identical step loads that correlate with picture brightness), the linkage enables all corresponding loads to be associated with a single appliance.

Methods for Determining the Most Probable Mapping of Appliances

The presently disclosed embodiment provides a method for determining the most probable mapping of appliances. In at least one implementation, the disclosed embodiment uses an STEC table to infer the most probable mapping of appliances. The STEC table is populated with all the transition sequences of length one seen.

The STEC table summarizes the linkages between transitions and steady state clusters and has the form:

| | | | | |
|---|---|---|---|---|
| STEC_ID | Start_SS_ID | Transition_ID | End_SS_ID | Count |

A closure rule can be defined as a sequence STEC records that have the End_SS_ID of one record equal to the Start_SS_ID of the next record. In addition the Start_SS_ID of the first record must be equal to the End_SS_ID of the last record.

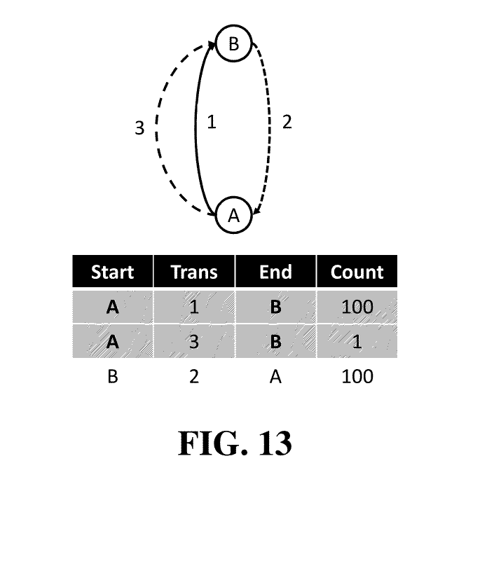

Due to the clustering method and the existence of numerous small loads on the circuit, inconsistences can develop in the STEC table. An inconsistency is defined as a two or more STEC records which are identical in their start and end steady state IDs but different in their transition IDs. FIG. 13 shows an example of beginning and ending in a steady state by different transitions. Steady state A can be traversed to steady state B by transition 1 or transition 3.

With the goal of mapping all transitions to one or more appliances whose states are defined in the Defined Steady State Table, inconsistencies pose the potential for non-unique solutions. A consistent STEC Table can be assembled, removing the inconsistencies by merging the corresponding STEC entries. Amongst the inconsistent sequence IDs in the STEC Table, the one with the highest count is recorded in the consistent STEC table. If the counts are equivalent, the first record is chosen. The new count value of the recorded sequence ID is the sum of all the counts of the inconsistent sequence IDs.

In one example the inconsistencies are queried from the STEC Table. In Table 20B, sequence IDs 3, 4 and sequences 5, 6, and 7 have inconsistencies. In the consistent table (Table 20C), the sequence with the highest count is chosen and the corresponding count of the sequence is updated.

TABLE 20B
STEC Table with inconsistent transitions.

| Sequence ID | Start_SS_ID | Transition_ID | End_SS_ID | Count |
|---|---|---|---|---|
| 3 | B | 3 | C | 1 |
| 4 | B | 7 | C | 10 |
| 5 | A | 6 | D | 2 |
| 6 | A | 7 | D | 3 |
| 7 | A | 2 | D | 40 |

TABLE 20C
STEC Table with consistent transitions.

| Sequence ID | Start_SS_ID | Transition_ID | End_SS_ID | Count |
|---|---|---|---|---|
| 3 | B | 7 | C | 11 |
| 4 | A | 2 | D | 45 |

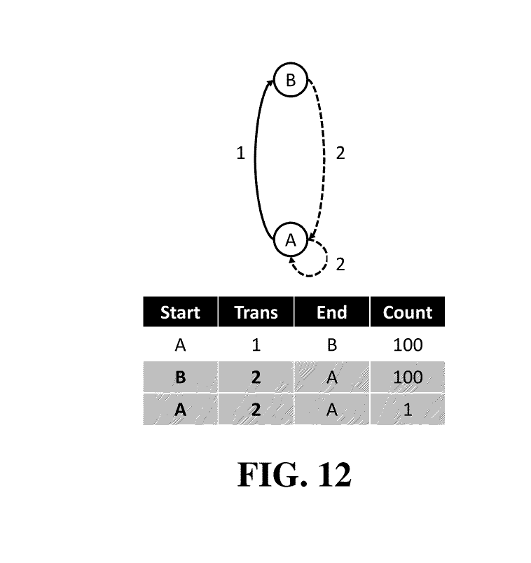

The consistent STEC table then can be processed to create a comprehensive list of closure rules. Closure rules of different lengths are extracted from the sequence of entries in the STEC. Each closure rule provides information on possible links between different transitions. Closure rules of length one occur when there is a transition but no change in the steady state. For those steady states, these transitions are regarded as null transitions. FIG. 12 has transition 2 going from steady state A to steady state A. After removing such rules from the consistent STEC table, an exhaustive search is performed to find the closure rules of length 2, 3 and 4.

Rules of length two specify two transitions which can be linked as opposites of each other. Each of the two transitions is either ON or OFF transition of an appliance.

Rules of length three link one transition to a combination of two other transitions. Rules of length 4, link two transitions to their opposite events, or three single transitions and a combination of the three transitions. If all the transitions and steady states are not covered by the rules of length two to four, higher length rule closure will be investigated until the rules touch all the transitions and steady states. Each of the higher length rules also links some transitions to their opposite transitions or to their combinations.

A transition mapping table is a table which summarizes all the transitions links to their opposites and combinations. In some examples, a transition mapping table includes the following columns:

| | | | |
|---|---|---|---|
| Transition ID | Opposites IDs | Combinations IDs | Probability |

The probability column lists the probability of occurrence of each transition. This probability value can be determined based on the counts of a transition in the STEC and the closure rules tables. The probability value can be used to select when there are inconstancies detected.

The transition mapping table can then be queried to determine the most likely linkages between SS_IDs, Transitions_IDs, and unlabeled loads.

In some embodiments, the Closure_Rule_Table is used as described herein to solve for the Defined Steady State table.

Method for a Labeling System to Identify Individual Signals

Also disclosed herein is a method for a labeling system to identify individual signals, such as individual signals generated from a device, including one or more appliances. In some embodiments, the method is applied in the field of Non-Intrusive Appliance Load Monitoring (NIALM) (such as to the field of decomposing a power meter signal into constituent loads to segregate and identify energy consumption associated with each individual load on the circuit). For example, the method includes presenting the results of the NIALM disaggregated load isolation data and providing an interface that allows the user to enter labeling information into the system to identify the individual appliances. In some embodiments, the method allows users, such as ratepayers, to be aware of their power expenses and to manage their use of energy as desired, such as more efficiently. In this implementation of NIALM, characteristic power signatures and usage patterns are automatically learned for each appliance. Usage patterns include, but are not limited to, the following: how long an appliance is used; length of time between usage; first usage each day (or any other defined time period); the last usage in a day; frequency of usage over time; minimum/maximum/average usage period in a day; minimum/maximum/total use in a day; minimum/maximum/average duty cycle (on time divide by total on+off time); use in conjunction with another appliance; or use of the appliance utility in conjunction with another utility; sequence of use in conjunction of another appliance or utility. In some embodiments, this information is used to isolate and identify the individual loads present in the one or more monitored circuits. In some examples, the signatures include high resolution sampled current and voltage values. The usage patterns include temporal information such as: frequency of use, usage duration, time of day usage, usage in conjunction with other utilities, usage in conjunction with other appliances, and the like or any combination thereof. Collectively the signatures and usage patterns form the profile for an appliance.

In the process of isolating a device from all the other devices, a library is built up of all the unique appliances detected. The library is initially empty and the load isolation/detection methods requires no a-prior knowledge, gradually building up the library as new appliances are discovered on the monitored circuit. The power signature recorded when an appliance is first detected is used as the bases for the future detection of that appliance. The usage pattern for each appliance is gradually built up over time as the appliance isolation algorithm continually determines when each appliance turns on and off.

In some examples, the disclosed NIALM method is able to successfully isolate all the key appliances in the one or more circuits being monitored as well as identify those appliances. Prior NIALM embodiments such as the Enetics SPEED use a-priory knowledge to perform this task. A library of appliance profiles exists prior to initiating measurements. When an appliance is isolated, the library is searched to find a matching appliance. If a match is found the identity of that appliance is implicitly known.

In an implementation of the disclosed method of NIALM, no a-priory knowledge is required to identify appliances. Characteristic power signatures and usage patterns are automatically learned for each appliance. This information is used to isolate and identify the individual loads present in the monitored circuit(s). In some embodiments, the signatures include high resolution sampled current and voltage waveforms. In some embodiments, the usage patterns include temporal information such as: frequency of use, usage length, time of day usage, usage in conjunction with other utilities, usage in conjunction with other appliances, and the like. Collectively the signatures and usage patterns form the profile for an appliance.

As stated previously, in the process of isolating a device from all the other devices, a library is built up of all the unique appliances detected. The library is initially empty and the load isolation/detection methods require no a-prior knowledge. Gradually, the library is built up as new appliances are discovered on the monitored circuit. In some embodiments, the power signature recorded when an appliance is first detected is used as the basis for the future detection of that appliance. The usage pattern for each appliance is automatically developed as the appliance isolation algorithm continually determines when each appliance turns on and off.

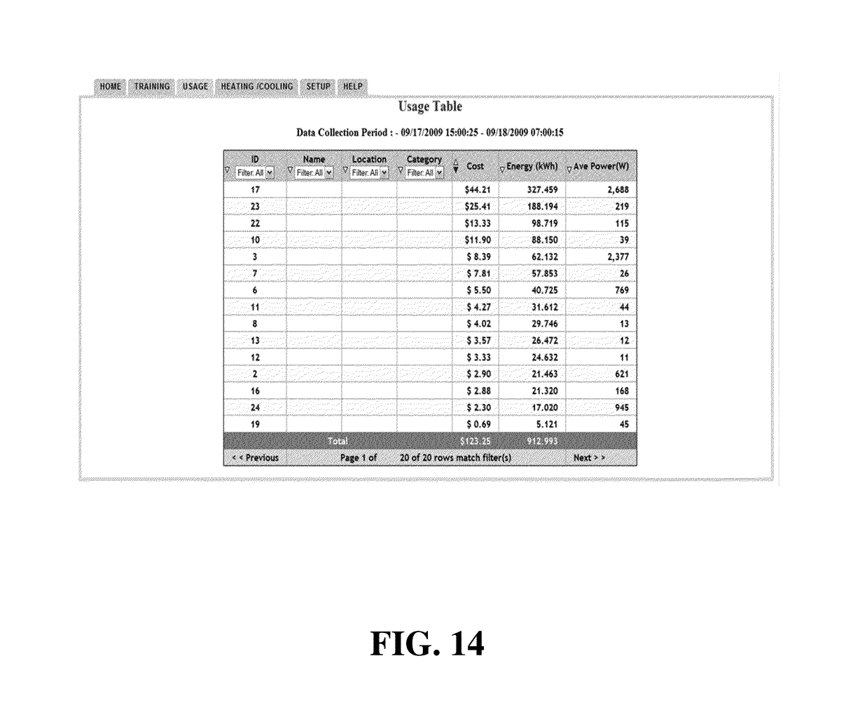

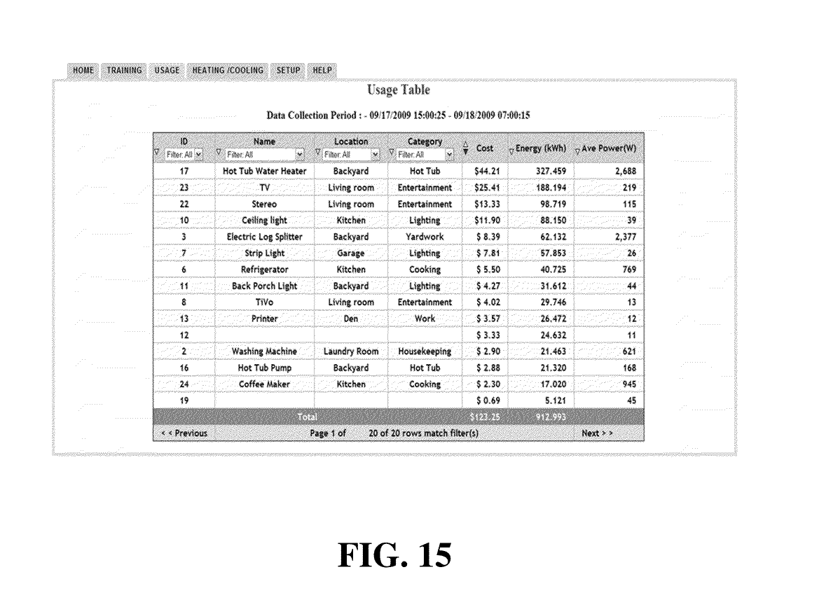

The disclosed method is also different than prior NIALM embodiments in that the disclosed method does not commence with a library of appliance profiles. As the algorithm progresses, the power consumption of each individual major appliance is isolated, however, the identity of that appliance is unknown. At this point, the system has successfully trained itself to recognize all occurrences of those appliances, from the total power usage, and allocated the associated energy usage and cost. An exemplary usage breakdown is shown in FIG. 14. In some examples, the breakdown is not yet useful to a user since the identity of each of the numbered appliances is not known. In such cases, the next task is to associate a label with each of the numbered appliances, i.e. to identify the appliances and produce a usage breakdown such as that shown in FIG. 15.

In some embodiments, a portion of this task is semi-automated in that suggestions are presented to the user for the identity of each appliance. Usage patterns of the device are examined and for those appliances that fit a particular pattern, suggestion(s) for the identity of the appliance are presented to the user; e.g. an appliance that runs periodically day and night, such as a refrigerator; an appliance that is the last appliance used before the house becomes inactive, or the first appliance used before the house becomes active could be a garage door opener.

Use of this method, comparing with known usage patterns, seems analogous to a system that uses a-priory knowledge. A difference is that the particular activity patterns are not pre-learned, it is only the attributes of the patterns that are pre-defined. For example, the specific on/off times of a refrigerator are not used to suggest the identity of the refrigerator, it is the fact that a refrigerator typically has a continuous repetitive fixed on/off duty cycle that is used.

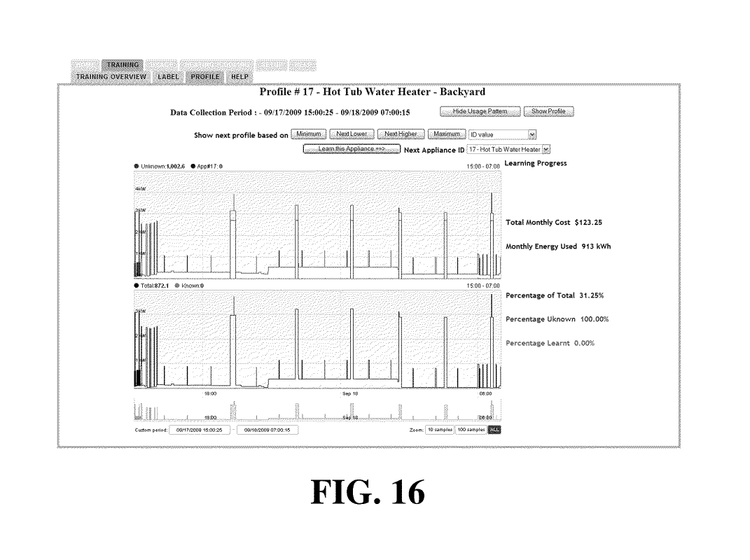

In some implementations, one or more appliances is identified. However, in other implementations, an appliance does not have usage patterns that are sufficiently distinct to reliably predict appliance type. In such implementations, a graphical labeling tool is employed. An example of this tool is shown in FIG. 16. FIG. 16 shows a time series of energy usage over a user selectable period of time. Four plot lines are used, two in the upper panel and two in the lower panel. Below the lower panel is a “zoom control” that allows the user to change the period of time that is displayed in both the upper and lower panels. The time series in the upper panel represents the power usage of all unknown appliances. The time series, initially zero, in the lower panel, represents all known (identified) appliances. The object of the user assisted labeling is to assign an identifying moniker to each major appliance so that it moves from the upper time series to the lower time series. The black (total) time series in the lower panel represents the total energy usage. The time series in the upper panel represents the energy usage of the currently selected appliance.

At the start of the user assisted labeling, the unknown appliances time series equals the black time series. However there is a pivotal difference between the two time series: the black (total) time series is the total power usage measured; whereas the unknown appliances time series is composed of the summation of the usage of each of the individual appliances isolated by the NIALM.

Each rising or falling step on a time series represents an event in which an appliance turns on or off, or its power usage changes. To label and identify an appliance, the user clicks on an event in the unknown time series. The user interface displays on the time series of the power usage of the appliance that caused the corresponding event on the unknown time series. The time series of the power usage of the appliance that caused the corresponding event on the unknown time series shows every event associated with the selected appliance over the plotted period. As is shown in FIG. 16, clicking the event at 19:12 results in the time series showing all the activity for appliance 17. This time series is the isolated power consumption of that one appliance and displaying its usage time series provides information for the user to help identify that appliance. Once the user has decided what appliance this time series represents, the user labels that appliance with a name/identifier and marks that appliance as known. Once marked as known the contribution of that appliance to the unknown appliances time series is subtracted and added to known or identified appliances time series. The user repeats the process of clicking on an interesting portion of the unknown time series, examining the resultant time series, labeling the resultant time series, and clicking on the learn button to subtract the resultant time series from the unknown time series; until all desired major appliances have been identified.

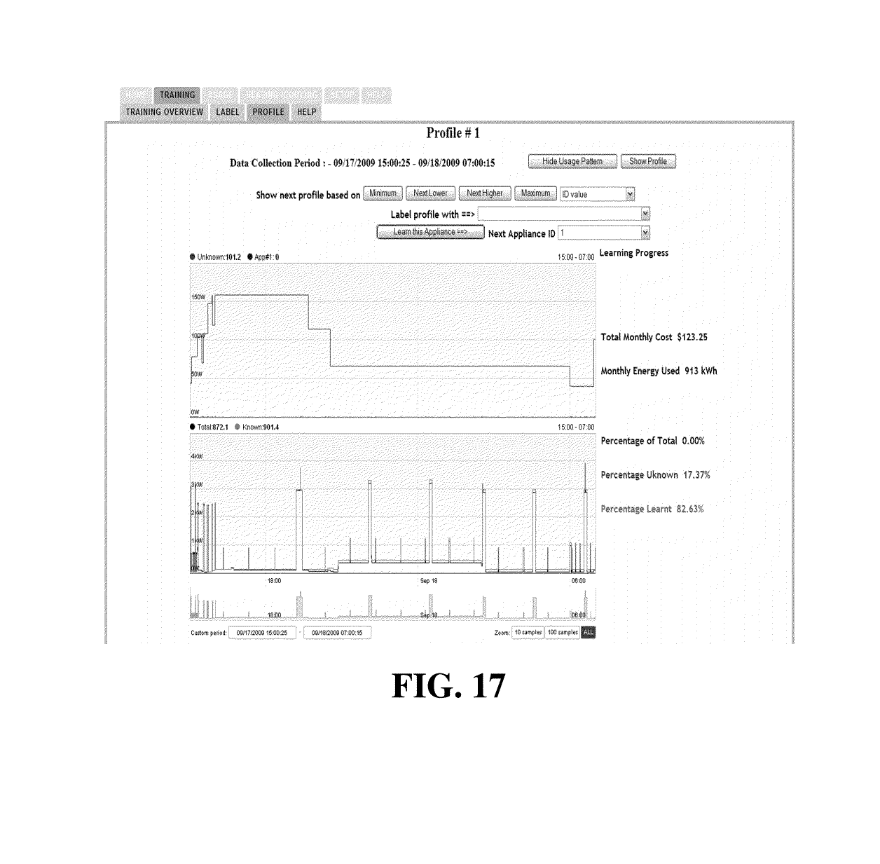

The user is constantly informed of the labeling progress by comparing the area under the black time series with the area under the known or identified appliances time series. Additionally as seen to the right of the plots in FIG. 17, a percentage progress indicator is shown. In this example 82.63% of the energy usage has been accounted.

The user assisted labeling can take place at any time, over any time period, and does not have to be performed all at once. A user may initially start to only label some of the major appliances isolated. The user may re-initiate labeling at a later point and e.g. only focus on appliances that turned on/off in the last hour. The ability to pick and choose when to label and to makes the method less arduous and the users only needs to label as little or as many isolated appliance as they perceive as being useful. Even without labeling, the device is able to disaggregate the power for the isolated appliances. Labeling is only required in order to attach a meaningful moniker to an isolate appliance.

Only a relative minimal effort is required by the user to perform this labeling and after about 15 minutes total labeling time the user ends up with a labeled system as shown in FIG. 17 in which more than 83% of the energy usage is known and the remaining 17% is mainly constant “background” energy usage. The background energy usage is the usage of the appliances which are always on, e.g. burglar alarm, fire alarm, DSL modem, wall hugger power supplies and other like appliances/devices. In an attempt to minimize the energy usage, a user can continue labeling the system and identify these smaller appliances. For many users in practice, the system can be labeled for all appliances in the home. The fact that the user is able to monitor/visualize the amount of “background” energy usage might alter a user's energy consumption, such as to cause a user to unplug or move to a power strip some of the unnecessary always “on” appliances.

In some embodiments, to assist in the labeling process one or more user interface features are implemented. Exemplary user interface features are described below. The following buttons/selectors cause power usage profiles to be shown on the upper panel according to various criteria.

i. Maximum Usage and/or Maximum Cost

In some implementations, “Maximum usage and/or Maximum cost buttons” sort the appliances with the largest power usage (or largest energy cost for users with time of use pricing) and display that appliance on the time series of the power usage of the appliance that caused the corresponding event on the unknown time series. Once labeled, and transferred to the known time series, the “max” button can be used again to find the unknown appliance with the next largest energy usage. This implementation is advantageous as it provides a very quick mechanism for the user to identify the most power consuming and/or expensive to operate appliances.

ii. Start Time

In some implementations, a “Start time” button finds the earliest, or latest, unknown appliance to be used within a user specified time period. For example, displaying the appliances that are used first thing in the morning allows a user to focus on labeling appliances that are typically used at the start of the day—toaster, waffle iron, coffee pot, hot water shower and other like devices/appliances. This feature is useful even after an appliance has been learned. In some examples, a manager of a large office environment can query the system and ask which office had their lights on after regular office hours. Information such as this could be used to monitor energy costs as well as providing security information.

iii. Duration of Use

In some implementations, a “Duration of use” button is employed to identify appliances that have been left on for a long period of time.

It is contemplated that additional user interface features can be utilized to facilitate the labeling and interpretation of the data including the examples provided below.

i. Undo Learning/Undo Labeling

In some implementations, an “Undo-learning/undo-labeling” button provides a mechanism for the user to correct errors made during the labeling process.

ii. Appliance ID Linkage

In some implementations, such as in the course of isolating appliances, the disclosed NIALM creates different power profiles for various operating loads or stable states of the same appliance; these profiles need to be linked to accurately allocate the total power usage of each appliance. For example, different profiles can be created for multi-stage appliances such as a washing machine; the profile for a wash cycle is different than the profile for a spin cycle. Additionally different profiles can be created for multi-load/multi-speed appliances such as a blender or power drill. The disclosed NIALM has techniques that can recognize these distinct profiles as being associated with one particular appliance. In some embodiments, an “Appliance linkage” button provides a mechanism for the user to manually join these two (or more) appliances as one and treat them as a single appliance in the energy usage analysis. This feature can also be used to join profile IDs for appliances that have substantially different turn on and turn off signatures.

iii. Appliance Split

In some implementations, two appliances will change state during the same transition period. A combination event is single event A, which is really composed of an appliance event B and an appliance event C. Appliance A does not exist, the close temporal proximity of the event for appliance B with the event for appliance C, causes only the single combination event, event A, to be detected. In some embodiments, the NIALM algorithm resolves combination events into the separate constituent (elemental) events. However, in some embodiments, such as if the NIALM algorithm inaccurately recognizes the combination event, rather than the constituent elemental events, it is necessary to provide the user with a mechanism to properly assign the combination into its elemental appliances. In such cases, an “Appliance split” button presents the user with potential elemental appliances whose combined associated events will equate to the combination event. The potential elemental appliances are automatically selected by an algorithm that attempts to improve the overall consistency of the on/off state of all the appliances. Additional, when these combinations are simultaneously shown to the user the user is able to very quickly see when a combination appliance needs to be split into the appropriate elements. When a combination profile is split accurately in this manner, the power associated with all events with this appliance identifier is split proportionally among the elemental appliances and corresponding events are generated for the elemental appliances.

The interface between the usage breakdown table, FIG. 15 and the labeling time series plots FIG. 17 is tightly coupled, allowing a user to quickly identify the appliances that are important to the user. For example, by clicking an appliance identifier number in the usage table the user is directly taken to the time series plot for that appliance.

This disclosed method using a graphical user interface to present the user a mechanism for labeling the NIALM processed data employs a self-learning approach. Prior to the NIALM disclosed herein, NIALM was configured to operate analogous to the way in which a neural network is labeled by repeatedly exposing a system to large set of inputs and outputs and allowing that system to adapt itself and learn the inherent relationship between the input/output data set.

In some implementations, labeling can be assisted by the user manual turning an appliance on or off. For example, at the same time, using a PC or a handheld device, such as a smart phone or tablet, the real-time power usage plot can be viewed. The recently generated event, the turning on/off of the appliance, will be displayed as a transition in the total power consumption plot. The user can click on that transition and the resultant display will show all isolated events for the appliance that generated that transition. The user can now label that isolated appliance.

Appliance Health Monitoring Device

Disclosed herein is a device which provides a mechanism for a user to see how the performance of an appliance has varied over time. By comparing the current transition profiles of an appliance to past historical snapshots of the transition profile, differences in the profile can be detected. In some embodiments, these differences indicate the early signs of a fault, e.g. loss of some refrigeration coolant causing a compressor to work harder, or a bearing problem in a fan causing more power to be used. In some embodiments, the device can inform the user of these issues and can automatically schedule a service call before the fault develops to a critical fault. The ability to predict future catastrophic failures is possible as the device is constantly monitoring the various appliances. This capability can result in significant saving to small businesses. For example, in the restaurant industry, being able to diagnose that a refrigeration unit needs to be serviced well before the temperature alarm sounds can result in significant savings by avoiding food spoilage. An additional savings could be to schedule the service call before the weekend when service rates are higher.

One embodiment of the device includes the capacity to self learn. Most learning systems require feedback, or a teaching input, which is used to correct what is learned. Other learning systems have a built-in database of golden models and use pattern matching between the inputs seen and the golden models. This embodiment has no a-priori knowledge, no teaching input, no pre-defined built in libraries and no connection to an external database with this information. As data is logged from the sensors, the device automatically extracted events, events are clustered to form closure rules, closure rules are used to associate each transition with an appliance or a combination of appliances. Given this automatically learned association, the device is able to disaggregate appliance energy usage data from the total energy usage.

Exemplary Computing Environment

The techniques and solutions described herein can be performed by software, hardware, or both, of a computing environment, such as one or more computing devices. For example, computing devices include server computers, desktop computers, laptop computers, notebook computers, handheld devices, netbooks, tablet devices, mobile devices, PDAs, and other types of computing devices.

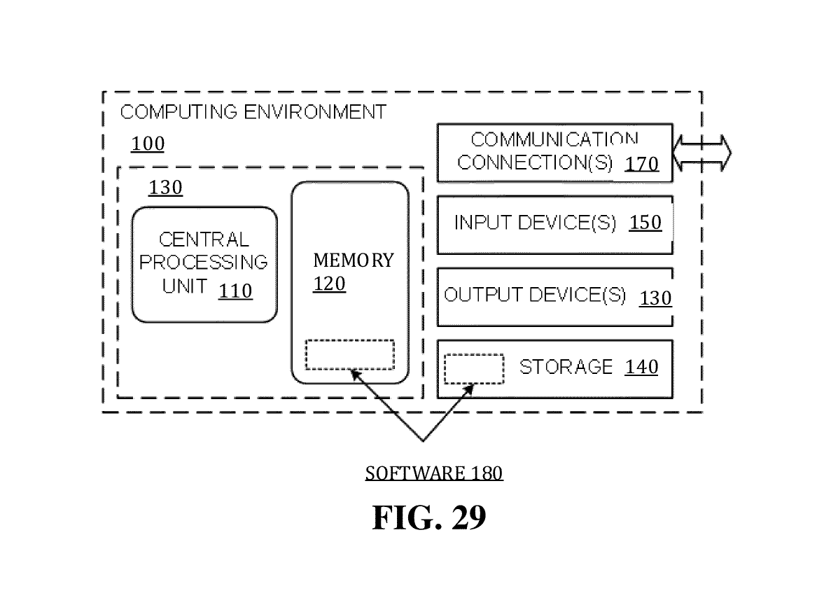

FIG. 29 illustrates a generalized example of a suitable computing environment 100 in which the described technologies can be implemented. The computing environment 100 is not intended to suggest any limitation as to scope of use or functionality, as the technologies may be implemented in diverse general-purpose or special-purpose computing environments. For example, the disclosed technology may be implemented using a computing device comprising a processing unit, memory, and storage, storing computer-executable instructions implementing methods disclosed herein. The disclosed technology may also be implemented with other computer system configurations, including hand held devices, multiprocessor systems, microprocessor-based or programmable consumer electronics, network PCs, minicomputers, mainframe computers, a collection of client/server systems, and the like. The disclosed technology may also be practiced in distributed computing environments where tasks are performed by remote processing devices that are linked through a communications network. In a distributed computing environment, program modules may be located in both local and remote memory storage devices.

With reference to FIG. 29, the computing environment 100 includes at least one processing unit 110 coupled to memory 120. In FIG. 29, this basic configuration 130 is included within a dashed line. The processing unit 110 executes computer-executable instructions and may be a real or a virtual processor. In a multi-processing system, multiple processing units execute computer-executable instructions to increase processing power. The memory 120 may be volatile memory (e.g., registers, cache, RAM), non-volatile memory (e.g., ROM, EEPROM, flash memory, etc.), or some combination of the two. The memory 120 can store software 180 implementing any of the technologies described herein.

A computing environment may have additional features. For example, the computing environment 100 includes storage 140, one or more input devices 150, one or more output devices 160, and one or more communication connections 170. An interconnection mechanism (not shown) such as a bus, controller, or network interconnects the components of the computing environment 100. Typically, operating system software (not shown) provides an operating environment for other software executing in the computing environment 100, and coordinates activities of the components of the computing environment 100.

The storage 140 may be removable or non-removable, and includes magnetic disks, magnetic tapes or cassettes, CD-ROMs, CD-RWs, DVDs, or any other computer-readable media which can be used to store information and which can be accessed within the computing environment 100. The storage 140 can store software 180 containing instructions for any of the technologies described herein.

The input device(s) 150 may be a touch input device such as a keyboard, mouse, pen, or trackball, a voice input device, a scanning device, a touchpad, or another device that provides input to the computing environment 100. Other input devices include analog to digital convertors that are attached to physical sensor that measure, physical quantities such as current, voltages, temperature, pressure, humidity and light levels. For audio, the input device(s) 150 may be a sound card or similar device that accepts audio input in analog or digital form, or a CD-ROM reader that provides audio samples to the computing environment. The output device(s) 160 may be a display, printer, speaker, CD-writer, or another device that provides output from the computing environment 100.

The communication connection(s) 170 enable communication over a communication mechanism to another computing entity. The communication mechanism conveys information such as computer-executable instructions, audio/video or other information, or other data. By way of example, and not limitation, communication mechanisms include wired or wireless techniques implemented with an electrical, optical, RF, infrared, acoustic, or other carrier.

The techniques herein can be described in the general context of computer-executable instructions, such as those included in program modules, being executed in a computing environment on a target real or virtual processor. Generally, program modules include routines, programs, libraries, objects, classes, components, data structures, etc., that perform particular tasks or implement particular abstract data types. The functionality of the program modules may be combined or split between program modules as desired in various embodiments. Computer-executable instructions for program modules may be executed within a local or distributed computing environment.

Methods in Computer-Readable Media

Any of the disclosed methods can be implemented as computer-executable instructions or a computer program product stored on one or more computer-readable storage media (e.g., non-transitory computer-readable media, such as one or more optical media discs such as DVD or CD, volatile memory components (such as DRAM or SRAM, or nonvolatile memory components such as hard drives) and executed on a computer (e.g., any commercially available computer, including smart phones, tablets, or other mobile devices that include computing hardware). Computer-readable media does not include propagated signals. Any of the computer-executable instructions for implementing the disclosed techniques as well as any data created and used during implementation of the disclosed embodiments can be stored on one or more computer-readable media (e.g., non-transitory computer-readable media). The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the internet, a wide-area network, a local-area network, a client-server network (such as a cloud computing network), or other such network using one or more network computers.

For clarity, only certain selected aspects of the software-based implementations are described. Other details that are well known in the art are omitted. For example, it should be understood that the disclosed technology is not limited to any specific computer language or program. For instance, the disclosed technology can be implemented by software written in C, C++, Java, Perl, Python, Ruby, JavaScript, Adobe Flash or any other suitable programming language. Likewise, the disclosed technology is not limited to any particular computer or type of hardware. Certain details of suitable computers and hardware are well known in the art and need not be set forth in detail in this disclosure.

Furthermore, any of the software-based embodiments (comprising, for example, computer-executable instructions for causing a computer to perform any of the disclosed methods) can be uploaded, downloaded or remotely accessed through a suitable communication means. Such suitable communication means include, for example, the internet, the World Wide Web, an intranet, cable (including fiber optic cable), magnetic communications, electromagnetic communications (including RF, microwave, and infrared communications), electronic communications, or other such communication means.

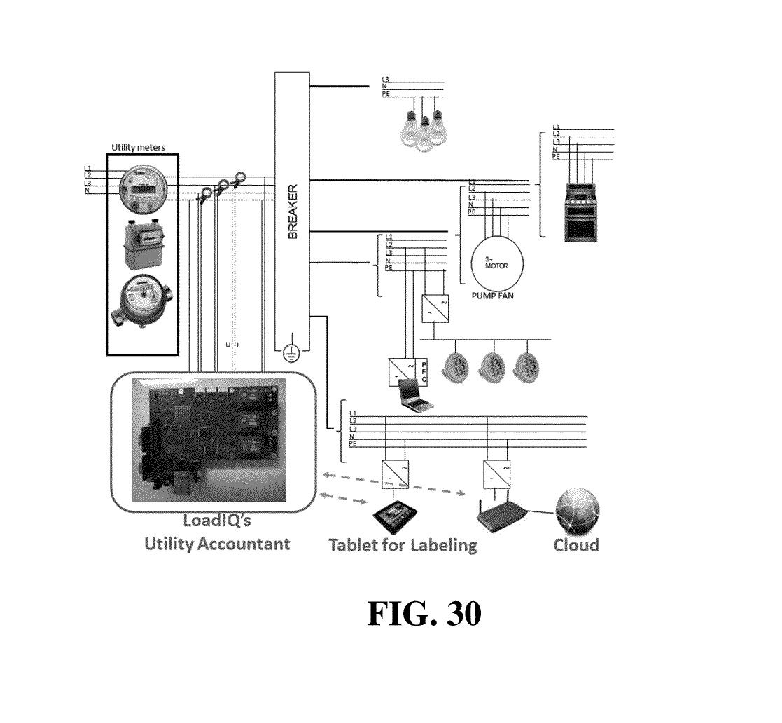

FIG. 30 provides a schematic of an exemplary environment for performing aspects of the disclosed methods and systems. In the schematic, a processing board including a disclosed signal identification system is coupled to a daughter board. The daughter board is additionally coupled to multiple devices via multiple detectors/sensors and to a network environment by an internet connection.

Alternatives

The disclosed methods and systems should not be construed as limiting in any way. Instead, the present disclosure is directed toward all novel and nonobvious features and aspects of the various disclosed embodiments, alone and in various combinations and subcombinations with one another. The disclosed methods and systems are not limited to any specific aspect or feature or combination thereof, nor do the disclosed embodiments require that any one or more specific advantages be present or problems be solved.

The disclosure is further illustrated by the following non-limiting Examples.

### EXAMPLES

### Example 1

This example shows the data generated during the use of a disclosed electrical load disaggregation system (referred to as a Utility Accountant (UA)) to monitor energy consumption in a residential setting.

Table 21 lists the various high energy appliances isolated by the UA on each leg or on both legs in the case of the 240 V appliances.

The “Baseline” energy figure shown is the amount of energy that was consumed on that leg by the “always on” appliances. Appliances can only be isolated by the UA if they change state; thus the always on appliances must be aggregated into a single bundle. Knowing the energy use of all always on appliances is useful for a consumer to identifying and mitigating these wasteful appliances.

TABLE 21
Report of Utility Account disaggregation performance for House #1

| | | End Sep. 21, 2009 5:00:00 PM | | | | 4.9 Days |
|---|---|---|---|---|---|---|
| | Start Sep. 16, 2009 | | | | % | Annual |
| | 7:00:00 PM | Power | | Energy | Energy | Cost @ |
| House 1 | Appliance Name | (W) | Events | (kWh) | on Leg | $.12/kWh |
| 240 V | Hot Tub Heater | 6006 | 74 | 29.9 | 99% | $256 |
| Leg 1 | Refrigerator | 181 | 103 | 17.2 | 87% | $153 |
| Leg 1 | Furnace Fan | 232 | 256 | 7.5 | 101% | $66 |
| Leg 2 | Attic Fan | 217 | 10 | 7.3 | 97% | $65 |
| Leg 2 | Crawl Space Fan | 120 | 12 | 4.9 | 96% | $44 |
| Leg 2 | Instant Hot Water | 950 | 274 | 3.7 | 99% | $33 |
| 240 V | Coffee Maker | 2091 | 287 | 3.2 | 104% | $29 |
| 240 V | Hot Tub Blower | 486 | 73 | 2.5 | 109% | $22 |
| 240 V | Large Stove Burner | 2841 | 154 | 1.9 | 103% | $17 |
| 240 V | Oven | 4371 | 28 | 1.8 | 101% | $13 |
| 240 V | Convection/Microwave | 1512 | 8 | 0.9 | 95% | $8 |
| 240 V | Small Stove Burner | 1397 | 118 | 0.8 | 103% | $7 |
| 240 V | Defroster | 364 | 22 | 0.6 | 190% | $6 |

| | | | | Annual |
|---|---|---|---|---|
| | | Energy | % of | Cost @ |
| House 1 Summary | | (kWh) | Measured | $.12/kWh |
| Leg 1 | Baseline | 34.0 | 24% | $303 |
| Leg 1 | Baseline + Isolated | 79.5 | 55% | $708 |
| | Appliances | | | |
| Leg 1 | Total Measured | 144.0 | 100% | $1,282 |
| Leg 2 | Baseline | 2.9 | 6% | $26 |
| Leg 2 | Baseline + Isolated | 36.7 | 75% | $327 |
| | Appliances | | | |
| Leg 2 | Total Measured | 48.7 | 100% | $434 |
| House | Baseline | 36.9 | 19% | $329 |
| House | Baseline + Isolated | 128.2 | 67% | $1,142 |
| | Appliances | | | |
| House | Total Measured | 192.7 | 100% | $1,716 |

The actual power used by an appliance was not the key aspect of how successfully it can be isolated. The key aspect was how much that appliance's power signature differed from those of other appliances. The algorithm was as adept at isolating small appliances, such as CF light bulbs, as it was at isolating large appliances, such as an oven.

Common energy efficiency decisions that can reliably be made with the data from the Utility Accountant:

### Example 1

The refrigerator in House 1 costs $153/yr to operate versus $50/yr for the similarly sized (20 cf) refrigerator in another house. These savings can be factored into the decision to purchase a new more efficient refrigerator (˜$800) that will have as simple payback period of 8 years.

### Example 2

House 1 uses a crawl-space fan ($44/yr) to remove moisture from under the house. An alternative method to remove moisture is with a sump pump that costs $450 to install, but operates infrequently and efficiently ($5/yr). The simple payback period for the sump pump is >10 years.

### Example 3

The heater in the spa in House 1 costs $300/yr to operate. A new cover costs $300 and has an insulation value of R-21 versus the stock cover that is rated at R-12 but may be performing below that rating because it is saturated with water. Assuming the new cover reduces energy costs by ⅓, the new cover will pay for itself in 3 years.

### Example 4

The baseline power in three houses ranged from $200 to $329/yr. A low/zero cost solution to reduce energy costs would be to find which of these appliances can be unplugged.

### Example 2

This example describes use of a disclosed electrical load disaggregation system (referred to as a Utility Accountant (UA)) and the use of such in Quick Serve facilities (including fast-food restaurants, gas stations, and mini-marts).

The average energy bill for a 3,000 square foot Quick Serve building is ˜$2,500 per month. The $6,000/year potential savings (based on 20% energy reduction) is much greater than in the residential market with savings of ˜$300/year for the average US household.

The clustering algorithm can be modified so that resistive transitions are clustered separately. The energy datasets collected in Example 1 show that numerous appliances can be classified as purely resistive in that they draw current proportionally to the real time voltage on the circuit. These appliances tended to be heaters or incandescent lights. The UA load disaggregation algorithm isolates appliances based on differences in their power signature. Resistive appliance signatures have little discriminatory value, as the signature can effectively be reduced to a single value in units of ohms, representing the voltage divided by the current. However, all resistive appliances observed in the test houses demonstrated two behaviors that can be used to facilitate their isolation from the remainder of appliances on the leg or circuit. First, the normalized power used by resistive appliances is very stable with less than 0.5% deviation observed with repeated actuation. Secondly, the on and off powers changes are nearly equivalent in magnitude. These behavioral differences can be exploited by first classifying the transition signatures as resistive, sinusoidal, or non-sinusoidal prior to clustering. Resistive transitions can be clustered using tighter similarity thresholds such that inter-cluster variation will be minimized. This step improves the separation of resistive appliances that are difficult to tell apart while still accommodating non-resistive appliances (such as the refrigerator) that may be associated with several loosely bound transition clusters.

### Example 3

This example describes an energy management application which allows energy consumption to be identified and managed.

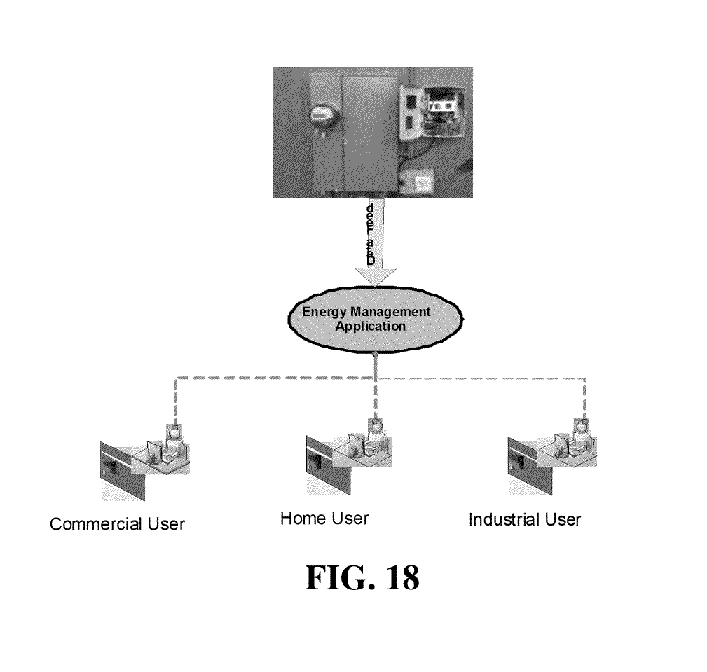

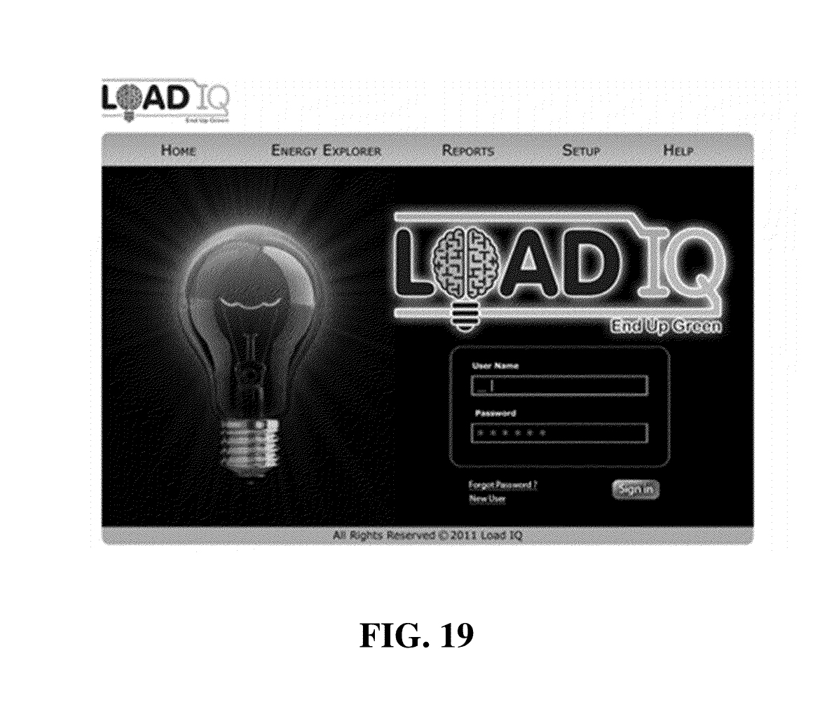

As illustrated in FIG. 18, data flowing from an installed device is transmitted, such as wirelessly transmitted, to a second device such as a mobile device, including, but not limited to laptop computer including an energy management application to allow energy consumption to be identified and managed. The energy management application is customized for the specific user—e.g., commercial, home, and/or industrial users. For example, the energy management application allows a user to generate reports so that they are most meaningful for such user (e.g., appliance loads are grouped according to business unit (such as gas pumps, slot machines, food storage, etc.), appliance type (HVAC, refrigeration, lighting, cooking), location (such as a parking lot, store front, dining room, kitchen, etc.) or any other criteria). FIG. 19 is a screen shot of an initial login screen of a disclosed energy management application in which users enter the user name and password.

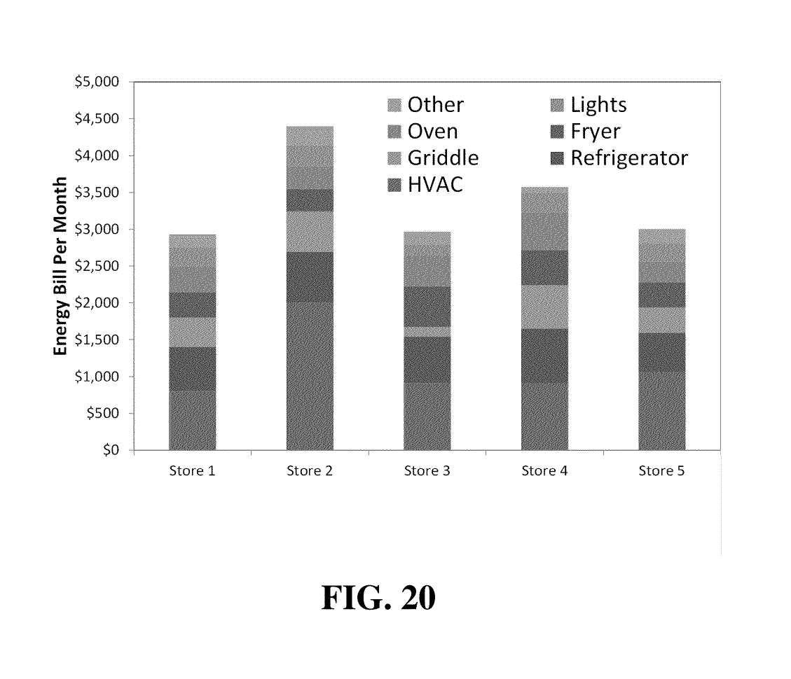

Once gaining access to the application, energy consumption can be identified and monitored using such application. For example, the energy management application includes a dashboard which displays energy consumption profiles for various locations or facilities. In one example, a disclosed energy management application is used by a multisite franchise owner in the food industry and such application includes multisite franchise energy dashboard allowing the multisite franchise owner to visualize energy consumption of various appliances at the various locations. FIG. 20 is a screenshot of an exemplary multisite franchise energy dashboard.

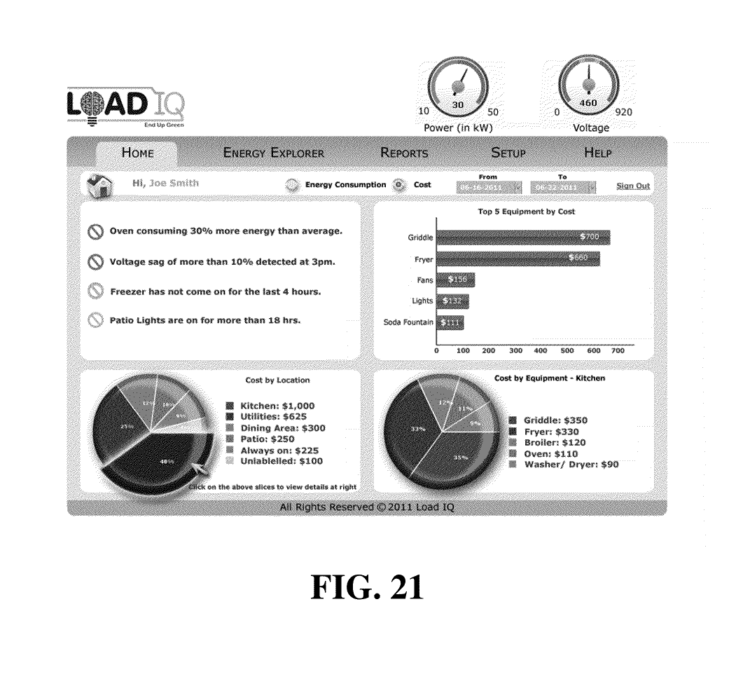

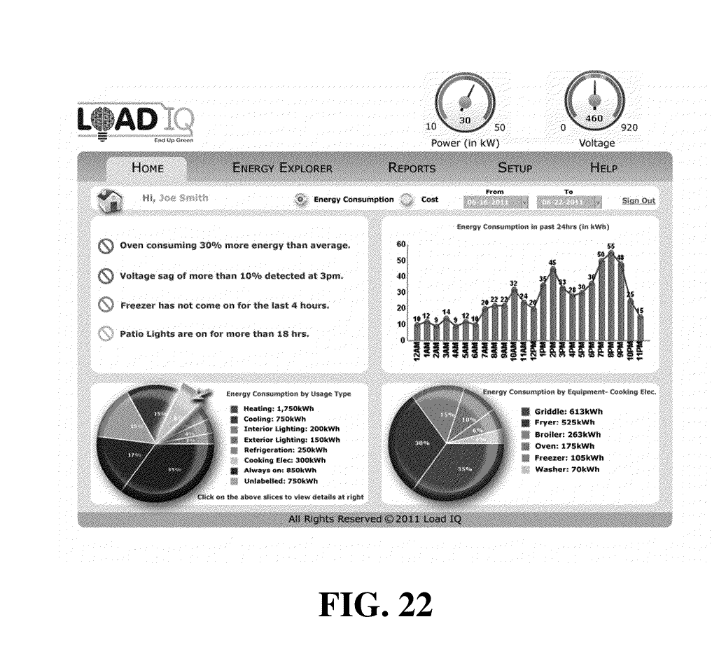

Food Service has the highest energy intensity of all commercial sectors. Huge waste has been documented by independent laboratories. For example, a typical fast food energy bill is $1500-$5000 per month. The PNNL 2010 Report estimated that 41% to 52% of such energy was wasted. In most cases, owners do not have easy access to the information they need to cut costs. Energy expenses are on the same order as profit. For a typical restaurant saving $500 is the same as selling 2000 more burgers. Therefore, taking steps to control energy costs is an attractive way to save money because one can save energy today, while increasing sales takes time. Thus, the disclosed application allows inefficient appliances and activities to be identified; the cost-benefit of appliance repair or replacement to calculated and peak demand to managed. For example, an owner has multiple franchises and only knows that each franchise has a specific energy bill, but does not know what appliance or activity contributes to what portion of such bill. Employing a disclosed energy management application an owner can identify the power usage of each or the most energy consuming appliances at each location. Upon identifying the various energy profiles for the specific appliances, energy consumption is calculated and then displayed to a user in a format (such as in a pie graph or bar graph) that is easily understood the energy consumption of each appliance. FIG. 21 presents a screen shot of an exemplary home page for the disclosed energy management application which provides a user actionable information and overview of one or more facility's energy consumption. As illustrated in FIG. 21, there are two dials at the top of the homepage that can be viewed in all screens. They provide current power usage and incoming power with a comparison to past average. The given home page shows warnings on the top left and top 5 energy consumers on the right. Users have the ability to change the time frame and toggle between Energy consumption and Cost view. Cost view is shown as an example herein. At the bottom right of the home page, physical location is taken as an example for Category. When a user clicks on a slice, the right side shows the details for that segment. FIG. 22 provides another version of a home page in which the bottom charts show Usage Type as an example for category. The top right shows energy consumption by the hour for the last 24 hours.

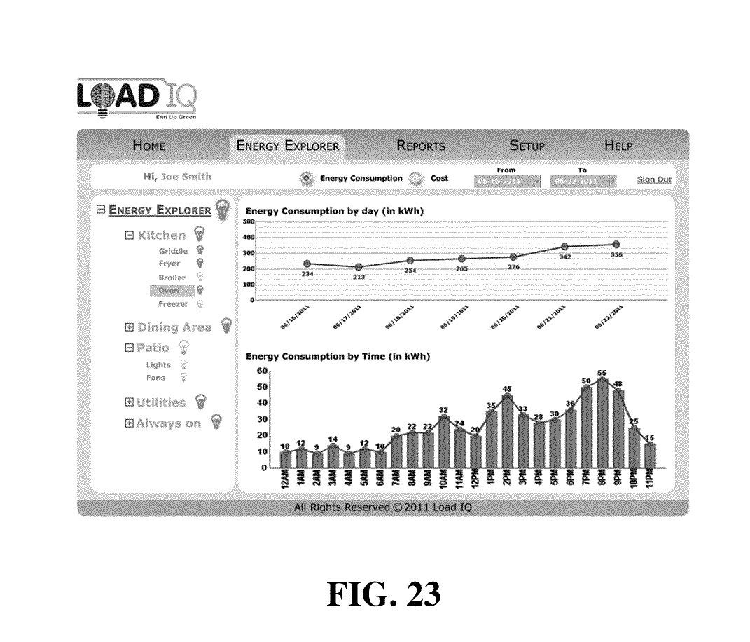

FIG. 23 is a screen shot of the Energy Explorer feature which provides a list of all Equipment grouped by Category in a hierarchical view. Users can collapse or expand the view. The light bulb icon indicates which equipment is currently on. When the users click on an Equipment they can see the details on the right. Users are able to view the Energy consumption and cost details and also choose a custom date range.

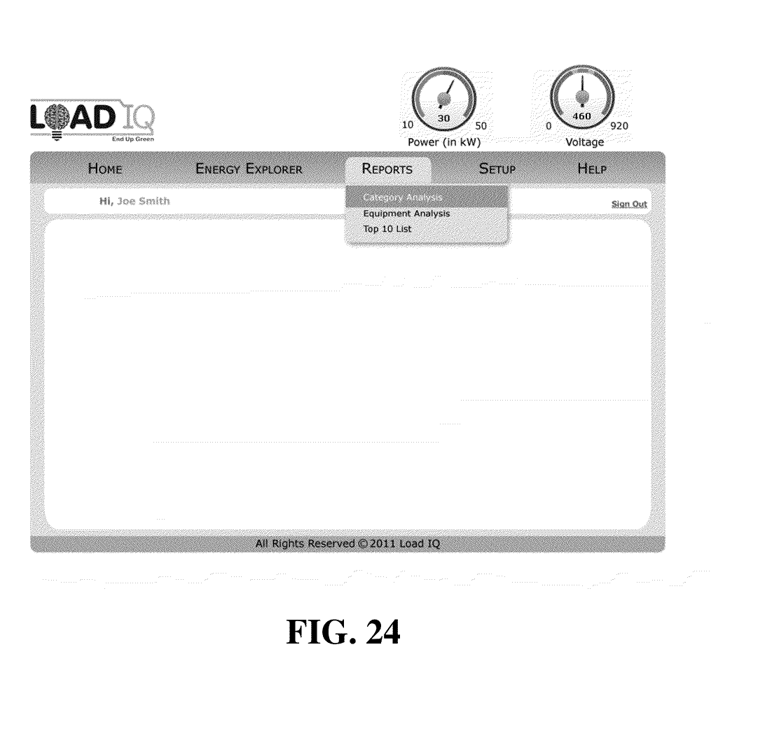

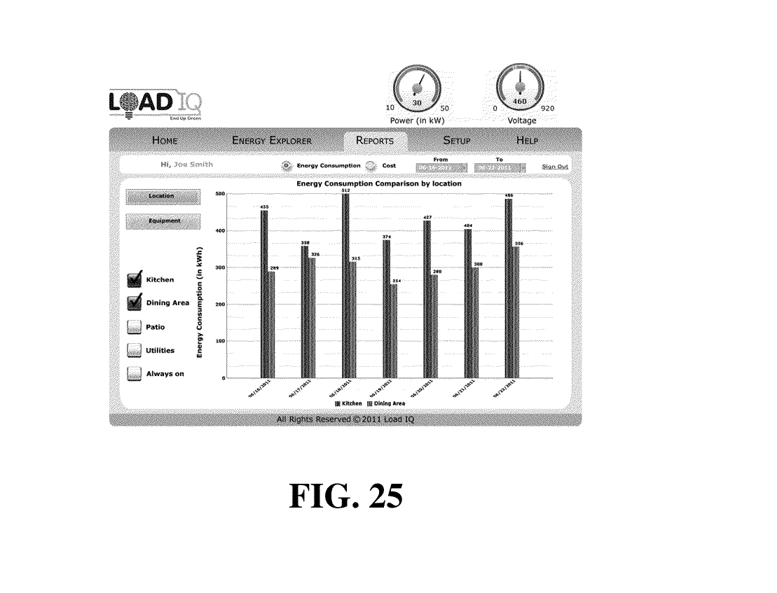

FIG. 24 is a screen shot of the report feature which allows a user to create a report by Category analysis (by location, usage type etc.), Equipment or by creating a top 10 list. For example, FIG. 25 is a screen shot of a report illustrating the Energy Consumption and Cost comparison by Category for a chosen time range by day.

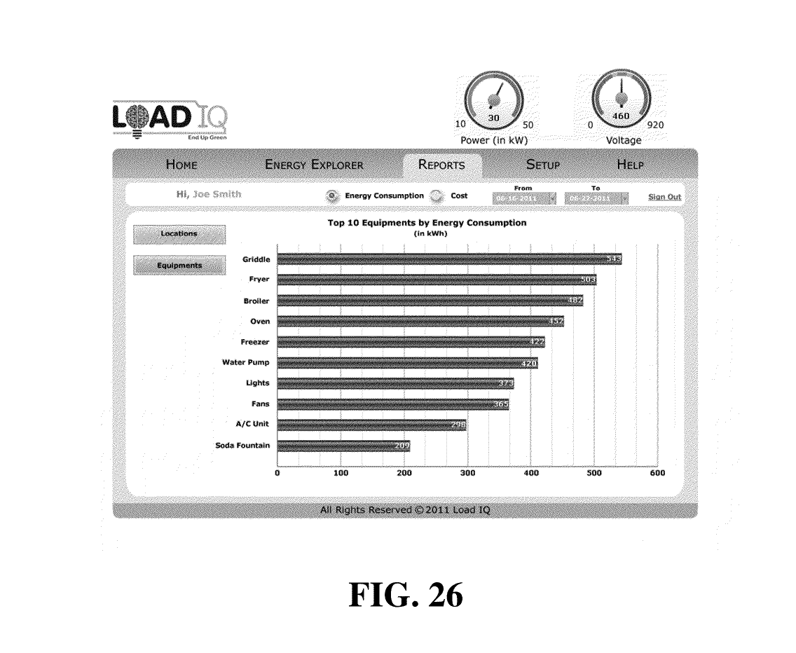

FIG. 26 is a screen shot of a report presenting the top 10 Equipments by energy consumption or cost for a chosen time range.

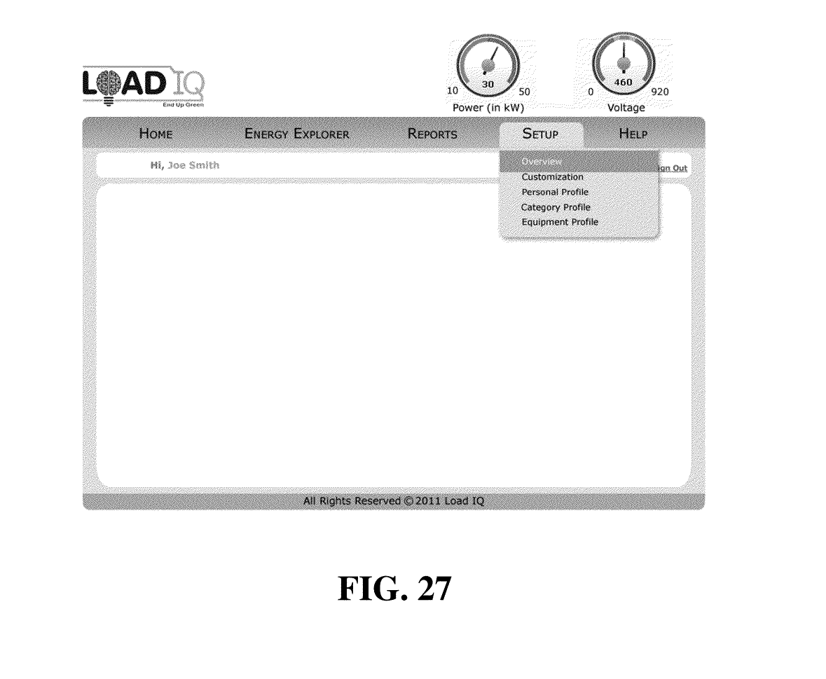

FIG. 27 is a screen shot of a Setup Menu illustrating various functions which a user may select to assist in setting up the energy management application. All the data given during the initial setup is stored in the Setup Menu. Further, users can change the data for on-going maintenance (e.g., New Equipment added, Existing Equipment relocated etc.).

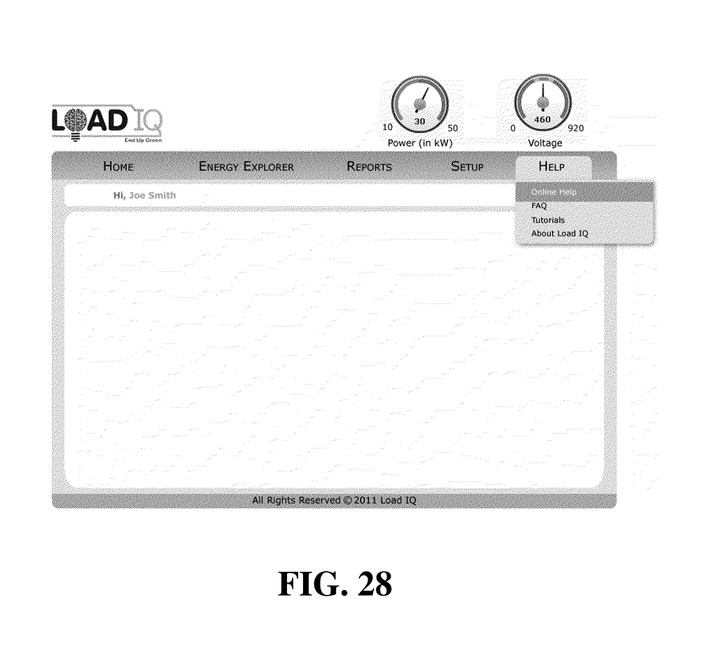

FIG. 28 is a screen shot of a Help Menu features available to a user. For example, a user may seek online help, refer to the frequently asked questions, access tutorials or access additional information about the energy management application (referred herein as Load IQ).

The Load Isolation algorithm involves multiple detailed steps to separate the load from the background. First the power signal is segmented into periods of transition and steady states. These segments are stored as individual waveforms of the 50 Hz power signatures (sampled at 256 samples per voltage cycle) along with the start and end times of the transitions periods. The waveforms are clustered together in a way that minimizes the Euclidian distance between members of a cluster. The power signal is then reduced to references to each Steady State and Transition cluster ID to extract patterns of load actuation.

It is to be understood that the above discussion provides a detailed description of various embodiments. The above descriptions will enable those skilled in the art to make many departures from the particular examples described above to provide apparatuses constructed in accordance with the present disclosure. The embodiments are illustrative, and not intended to limit the scope of the present disclosure. The scope of the present disclosure is rather to be determined by the scope of the claims as issued and equivalents thereto.

1. A method for determining whether a load is in a steady state or in transition, the method comprising:
analyzing a time series of electric power or current measurements on at least one circuit, at least one load coupled to the at least one circuit; and
determining whether the load is in a steady state or a transition.

2. The method of claim 1, further comprising comparing the average and variance of the time series.

3. The method of claim 1, further comprising comparing the absolute value of a value obtained by comparing the average and variance of a time series to a threshold.

4. The method of claim 3, further comprising determining that the load is in transition when the absolute value if greater than the threshold.

5. A method for tracking the state of an appliance comprising:
determining a power sequence for a steady state electrical signal;
calculating steady state and transition waveforms for the power sequence;
clustering steady state waveforms, with each cluster representing the same set of appliances being either on and or off;
clustering transition waveforms with each cluster representing the same transition, on or off for an appliance; and
determining all unique sequences of start steady state waveform cluster, transition waveform cluster, end steady state transition cluster (STEC); and
assigning an occurrence count to each STEC sequence.

6. The method of claim 5, further comprising eliminating inconsistent STECs.

7. The method of claim 5, further comprising determining a closure rule, the closure rule comprising, for a particular steady state, determining the transition sequence to the next steady state in the same steady state cluster.

8. The method of claim 5, further comprising eliminating closure rules that are trivial.

9. The method of claim 5, wherein complementary on/off transitions within the closure rules are associated with an appliance.

10. The method of claim 5, wherein composite transitions within the closure rules are associated with a combination of on/off transitions of appliances.

11-13. (canceled)

14. An appliance identification method, comprising:
determining the set of closure rules of size two that begin at a new steady state;
determining defined steady states from the set of closure rules of size two; and
adding defined steady states to a set of defined steady states.

15. The method of claim 14, wherein the set of defined steady states initially consists of the steady state that uses the least amount of power.

16. The method of claim 14, wherein the set of defined steady states initially consists of the defined steady state corresponding to all loads associated with a monitored circuit consuming zero energy.

17. The method of claim 14, further comprising determining closure rules of size 3 that apply to the set of defined steady states.

18. The method of claim 14, further comprising determining closure rules of size 4 or greater that apply to the set of defined steady states.

19. The method of claim 14, further comprising identifying appliances having multiple interrelated states of operation.

20. The method of claim 14, further comprising identifying multiple appliances that produce identical transition signatures.

21. The method of claim 14, further comprising identifying loads that give rise to redundant steady states.

22-28. (canceled)
